(19) United States
(12) Patent Application Publication
(10) Pub. No.: US 2015/0294991 A1
(43) Pub. Date: Oct. 15, 2015

(54) SEMICONDUCTOR DEVICE, ELECTRONIC COMPONENT, AND ELECTRONIC DEVICE

(71) Applicant: Semiconductor Energy Laboratory Co., Ltd., Atsugi-shi (JP)

(72) Inventor: Takahiko ISHIZU, Atsugi (JP)

(21) Appl. No.: 14/679,139

(22) Filed: Apr. 6, 2015

(30) Foreign Application Priority Data
Apr. 10, 2014 (JP) 2014-080845

(51) Int. Cl. H01L 27/12; H01L 29/24; G11C 14/00

(52) U.S. Cl. CPC H01L 27/1207; G11C 14/0054; H01L 29/24

(57) ABSTRACT

A semiconductor device having a novel structure. A multiport SRAM and a data memory portion including an OS transistor are stacked. Since the multiport SRAM includes more wirings and transistors, an area increase is not caused by an increase in the number of transistors in the data memory portion including an OS transistor. An increase in the number of transistors in the data memory portion enables static operation. Thus, the data memory portion can achieve stable recovery operation, higher speed operation, and simplification.

### BACKGROUND OF THE INVENTION

1. Field of the Invention

One embodiment of the present invention relates to a semiconductor device, an electronic component, or an electronic device.

Note that one embodiment of the present invention is not limited to the above technical field. The technical field of the invention disclosed in this specification and the like relates to an object, a method, or a manufacturing method. In addition, one embodiment of the present invention relates to a process, a machine, manufacture, or a composition of matter. Specifically, examples of the technical field of one embodiment of the present invention disclosed in this specification include a semiconductor device, a display device, a light-emitting device, a power storage device, a memory device, a method of driving any of them, and a method of manufacturing any of them.

2. Description of the Related Art

Static random access memories (SRAMs) are used as cache memories of processors or the like because data writing/reading can be performed at high speed.

Since SRAMs are volatile memories, data is lost when power supply is stopped. Therefore, the following structure is proposed: a transistor including an oxide semiconductor in a semiconductor layer in which a channel is formed (an OS transistor) and a capacitor are added to an SRAM so that loss of data is prevented (see Patent Document 1, for example).

### REFERENCE

### Patent Document

Patent Document 1: Japanese Published Patent Application No. 2013-008437

### SUMMARY OF THE INVENTION

The structure for preventing loss of data requires more components such as wirings and/or transistors. Such an increase in components is expected to cause no increase in layout area.

An object of one embodiment of the present invention is to provide a novel semiconductor device or the like.

Another object of one embodiment of the present invention is to provide a semiconductor device or the like having a novel structure which can include more components without an increase in layout area. Another object of one embodiment of the present invention is to provide a semiconductor device or the like having a novel structure which can operate at higher speed.

Note that the objects of one embodiment of the present invention are not limited to the above objects. The objects described above do not disturb the existence of other objects. The other objects are the ones that are not described above and will be described below. The other objects will be apparent from and can be derived from the description of the specification, the drawings, and the like by those skilled in the art. One embodiment of the present invention is to solve at least one of the above objects and the other objects.

One embodiment of the present invention is a semiconductor device comprising a multiport SRAM comprising a first transistor and a wiring electrically connected to the first transistor and a data memory portion comprising a second transistor and a capacitor. The first transistor comprises silicon in a channel formation region. The second transistor comprises an oxide semiconductor in a channel formation region. One of a source and a drain of the second transistor is electrically connected to a source or a drain of the first transistor. The capacitor is electrically connected to the other of the source and the drain of the second transistor. The source or the drain of the first transistor overlaps with the wiring. The wiring overlaps with the source or the drain of the second transistor. The source or the drain of the second transistor overlaps with an electrode of the capacitor.

One embodiment of the present invention is a semiconductor device comprising a multiport SRAM comprising a first transistor and a wiring electrically connected to the first transistor and a data memory portion comprising a second transistor, a third transistor, and a capacitor. The first transistor comprises silicon in a channel formation region. The second transistor comprises an oxide semiconductor in a channel formation region. The third transistor comprises silicon in a channel formation region. One of a source and a drain of the second transistor is electrically connected to a source or a drain of the first transistor. The capacitor is electrically connected to the other of the source and the drain of the second transistor. The other of the source and the drain of the second transistor is electrically connected to a gate of the third transistor. A source or a drain of the third transistor is electrically connected to the source or the drain of the first transistor. The source or the drain of the first transistor overlaps with the wiring. The wiring overlaps with the source or the drain of the second transistor. The source or the drain of the second transistor overlaps with an electrode of the capacitor.

In one embodiment of the present invention, the third transistor is preferably an n-channel transistor or a p-channel transistor included in an inverter.

Note that other embodiments of the present invention will be described in the following embodiments with reference to the drawings.

According to one embodiment of the present invention, a semiconductor device or the like having a novel structure can be provided.

Alternatively, according to one embodiment of the present invention, a semiconductor device or the like having a novel structure which can include more components without an increase in layout area can be provided. Consequently, a smaller semiconductor device or the like having a novel structure can be provided according to one embodiment of the present invention. Alternatively, according to one embodiment of the present invention, a semiconductor device or the like having a novel structure which can operate at higher speed can be provided.

Note that the effects of one embodiment of the present invention are not limited to the above effects. The effects described above do not disturb the existence of other effects. The other effects are the ones that are not described above and will be described below. The other effects will be apparent from and can be derived from the description of the specification, the drawings, and the like by those skilled in the art. One embodiment of the present invention is to have at least one of the above effects and the other effects. Accordingly, one embodiment of the present invention does not have the above effects in some cases.

### BRIEF DESCRIPTION OF THE DRAWINGS

In the accompanying drawings:

FIGS. 1A and 1B are a circuit diagram and a schematic view illustrating one embodiment of the present invention;

FIG. 2 is a circuit diagram illustrating one embodiment of the present invention;

FIGS. 3A to 3B4 are a schematic view and top views illustrating one embodiment of the present invention;

FIG. 4 is a cross-sectional view illustrating one embodiment of the present invention;

FIG. 5 is a cross-sectional view illustrating one embodiment of the present invention;

FIGS. 6A and 6B are a circuit diagram and a timing chart illustrating one embodiment of the present invention;

FIGS. 7A and 7B are circuit diagrams illustrating one embodiment of the present invention;

FIGS. 8A and 8B are circuit diagrams illustrating one embodiment of the present invention;

FIG. 9 is a circuit diagram illustrating one embodiment of the present invention;

FIGS. 10A and 10B are circuit diagrams illustrating one embodiment of the present invention;

FIGS. 11A and 11B are circuit diagrams illustrating one embodiment of the present invention;

FIG. 12 is a circuit diagram illustrating one embodiment of the present invention;

FIGS. 13A and 13B are timing charts illustrating one embodiment of the present invention;

FIG. 14 is a timing chart illustrating one embodiment of the present invention;

FIG. 15 illustrates operation of one embodiment of the present invention;

FIG. 16 is a block diagram illustrating one embodiment of the present invention;

FIG. 17 is a block diagram illustrating one embodiment of the present invention;

FIGS. 18A to 18C are high-resolution TEM images and local Fourier transform images of a cross section of an oxide semiconductor;

FIGS. 19A and 19B are nanobeam electron diffraction patterns of oxide semiconductor films, and FIGS. 19C and 19D illustrate an example of a transmission electron diffraction measurement apparatus;

FIG. 20 shows a change in crystal parts by electron beam irradiation;

FIG. 21A shows an example of structural analysis by transmission electron diffraction measurement and FIGS. 21B and 21C are high-resolution planar TEM images;

FIG. 22A is a flowchart showing a manufacturing process of an electronic component, and FIG. 22B is a schematic perspective view of the electronic component;

FIGS. 23A to 23E illustrate electronic devices including electronic components;

FIGS. 24A and 24B are circuit diagrams illustrating one embodiment of the present invention;

FIGS. 25A and 25B are circuit diagrams illustrating one embodiment of the present invention; and

FIG. 26 is a circuit diagram illustrating one embodiment of the present invention.

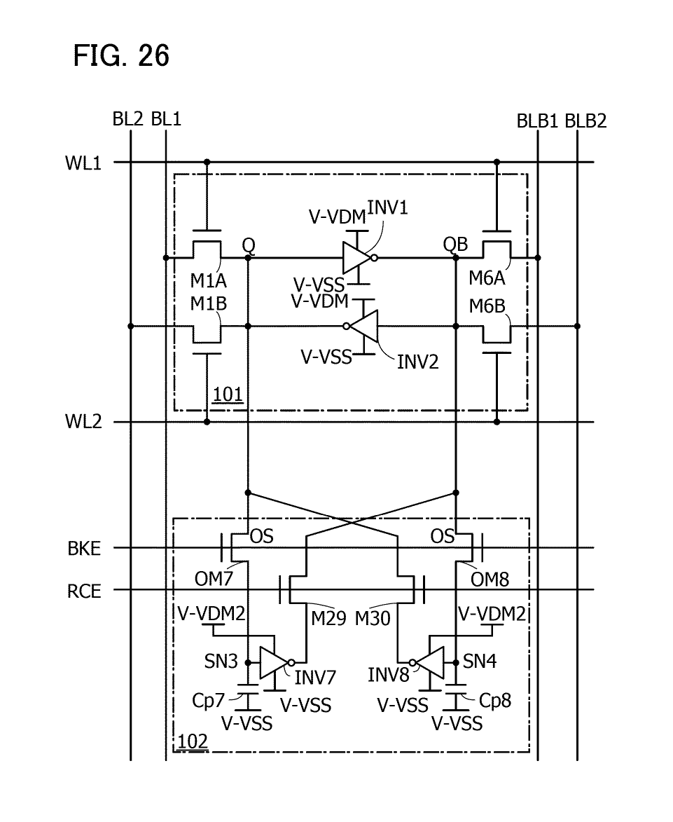

### DETAILED DESCRIPTION OF THE INVENTION

Hereinafter, embodiments will be described with reference to the drawings. Note that the embodiments can be implemented in various different ways and it will be readily appreciated by those skilled in the art that modes and details of the embodiments can be changed in various ways without departing from the spirit and scope of the present invention. The present invention therefore should not be construed as being limited to the following description of the embodiments.

In the drawings, the size, the layer thickness, or the region is exaggerated for clarity in some cases. Therefore, embodiments of the invention are not limited to such scales. Note that the drawings are schematic views showing ideal examples, and embodiments of the present invention are not limited to the shapes or the values in the drawings. For example, variation in signal, voltage, or current due to noise or difference in timing can be included.

In this specification and the like, a transistor is an element having at least three terminals: a gate, a drain, and a source. The transistor includes a channel region between the drain (a drain terminal, a drain region, or a drain electrode) and the source (a source terminal, a source region, or a source electrode) and current can flow through the drain, the channel region, and the source.

Here, since the source and the drain of the transistor change depending on the structure, the operating condition, and the like of the transistor, it is difficult to define which is a source or a drain. Thus, a portion that functions as a source or a portion that functions as a drain is not referred to as a source or a drain in some cases. In that case, one of the source and the drain might be referred to as a first electrode, and the other of the source and the drain might be referred to as a second electrode.

In this specification, ordinal numbers such as “first”, “second”, and “third” are used to avoid confusion among components, and thus do not limit the number of the components.

Note that in this specification, the expression “A and B are connected” or “A is connected to B” means the case where A and B are electrically connected to each other as well as the case where A and B are directly connected to each other. Here, the expression “A and B are electrically connected” means the case where electric signals can be transmitted and received between A and B when an object having any electric action exists between A and B.

Note that, for example, the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to a part of Z1 and another part of Z1 is directly connected to X while a drain (or a second terminal or the like) of the transistor is directly connected to a part of Z2 and another part of Z2 is directly connected to Y, can be expressed by using any of the following expressions.

The expressions include, for example, “X, Y, a source (or a first terminal or the like) of a transistor, and a drain (or a second terminal or the like) of the transistor are electrically connected to each other, and X the source (or the first terminal or the like) of the transistor, the drain (or the second terminal or the like) of the transistor, and Y are electrically connected to each other in this order”, “a source (or a first terminal or the like) of a transistor is electrically connected to X a drain (or a second terminal or the like) of the transistor is electrically connected to Y, and X the source (or the first terminal or the like) of the transistor, the drain (or the second terminal or the like) of the transistor, and Y are electrically connected to each other in this order”, and “X is electrically connected to Y through a source (or a first terminal or the like) and a drain (or a second terminal or the like) of a transistor, and X the source (or the first terminal or the like) of the transistor, the drain (or the second terminal or the like) of the transistor, and Y are provided to be connected in this order”. When the connection order in a circuit configuration is defined by an expression similar to the above examples, a source (or a first terminal or the like) and a drain (or a second terminal or the like) of a transistor can be distinguished from each other to specify the technical scope. Note that these expressions are only examples and one embodiment of the present invention is not limited to the expressions. Here, X, Y, Z1, and Z2 each denote an object (e.g., a device, an element, a circuit, a wiring, an electrode, a terminal, a conductive film, and a layer).

In this specification, terms for describing arrangement, such as “over” and “under,” are used for convenience for describing the positional relation between components with reference to drawings. The positional relation between components is changed as appropriate in accordance with a direction in which each component is described. Thus, there is no limitation on terms used in this specification, and description can be made appropriately depending on the situation.

Note that the layout of circuit blocks in a block diagram in a drawing specifies the positional relation for description. Thus, even when a drawing shows that different functions are achieved in different circuit blocks, an actual circuit block may be configured so that the different functions are achieved in the same circuit block. The functions of circuit blocks in diagrams are specified for description, and even in the case where one circuit block is illustrated, blocks might be provided in an actual circuit block so that processing performed by one circuit block is performed by a plurality of circuit blocks.

In this specification, the term “parallel” indicates that the angle formed between two straight lines is greater than or equal to −10° and less than or equal to 10°, and accordingly also includes the case where the angle is greater than or equal to −5° and less than or equal to 5°. In addition, the term “perpendicular” indicates that the angle formed between two straight lines is greater than or equal to 80° and less than or equal to 100°, and accordingly includes the case where the angle is greater than or equal to 85° and less than or equal to 95°.

In this specification, trigonal and rhombohedral crystal systems are included in a hexagonal crystal system.

### Embodiment 1

In this embodiment, circuit diagrams, top views, cross-sectional views, and a timing chart of a semiconductor device are described.

In this specification and the like, a semiconductor device means all devices that can function by utilizing semiconductor characteristics. The term “semiconductor device” refers to a memory such as a cache formed using semiconductor elements, e.g., transistors, peripheral circuits for controlling the memory, a CPU which inputs/outputs a signal to/from the memory and the peripheral circuits, a power supply voltage supplying circuit, a power management unit, and the entire system including the circuits.

### <Configuration of Memory Cell MC>

As one embodiment of the semiconductor device, a configuration of a memory cell MC is described.

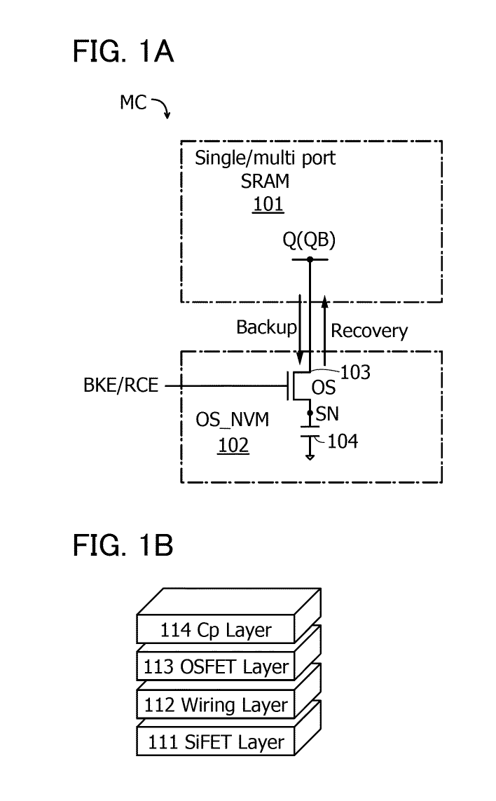

FIG. 1A is an outline circuit diagram of the memory cell MC.

The memory cell MC illustrated in FIG. 1A includes an SRAM 101 and a data memory portion 102. The data memory portion 102 includes a transistor 103 and a capacitor 104.

The SRAM 101 is a common SRAM, an example of which is a circuit including six transistors. The SRAM 101 can write/read data at high speed. Data in the SRAM 101 is lost when a power supply voltage is not supplied.

The SRAM 101 is connected to one or a plurality of ports which read and/or write data. The ports may be provided as a pair of wirings so as to output data and inverted data may be provided as one wiring. As the number of ports increases, the number of wirings also increases. The SRAM 101 may be a single-port SRAM with one port or a multiport SRAM with a plurality of ports.

The transistor in the SRAM 101 is a transistor including silicon in a semiconductor layer (a Si transistor). The SRAM 101 has an inverter loop including an inverter and can hold a potential corresponding to data. In FIG. 1A, a node holding a potential is denoted by Q(QB).

The data memory portion 102 corresponds to the node Q(QB). Backup and recovery by the data memory portion 102 are controlled by a backup/recovery control line BKE/RCE. The data memory portion 102 is a circuit having a function of backing up (also referred to as saving) data stored in the SRAM 101. Furthermore, the data memory portion 102 is a circuit having a function of recovering (also referred to as restoring) data backed up.

The transistor 103 is a transistor having a lower off-state current than a Si transistor. The capacitor 104 is connected to a source or a drain of the transistor 103. In FIG. 1A, a node connecting the transistor 103 and the capacitor 104 is denoted by SN. The node SN can hold charge when the transistor 103 is turned off.

An example of the transistor having a lower off-state current than a Si transistor includes a transistor including an oxide semiconductor in a semiconductor layer (an OS transistor). The off-state current of an OS transistor can be extremely low by reducing the concentration of impurities in the oxide semiconductor to make the oxide semiconductor intrinsic or substantially intrinsic.

In the configuration of the memory cell MC in FIG. 1A, when the transistor 103 is turned on, the potential of the node Q(QB) can be supplied to the node SN. When the transistor 103 is turned off, charge corresponding to the potential can be constantly held at the node SN. The charge can be constantly held even after supply of the power supply voltage is stopped, and therefore the data memory portion 102 can be nonvolatile.

Note that in a period during which holding the potential is held, a predetermined voltage is continuously supplied to the transistor 103 in some cases. For example, a voltage that completely turns off the transistor might keep being supplied to a gate of the transistor 103. Alternatively, a voltage that shifts the threshold voltages to allow the transistor to exist in a normally-off state may keep being supplied to a back gate of the transistor 103. In these cases, a voltage is supplied to the data memory portion 102 in the period during which data is held; however, little power is consumed because almost no current flows. Because of little power consumption, the data memory portion 102 can be regarded as being substantially nonvolatile even if a predetermined voltage is supplied to the data memory portion 102.

In a circuit diagram, “OS” is written beside a transistor in order to indicate that the transistor is an OS transistor. The OS transistor is an n-channel transistor unless otherwise specified. Therefore, in the transistor 103, when a signal supplied to the gate is at H level, there is a state of electrical conductivity between a source and a drain and when a signal supplied to the gate is at L level, there is a state of non-electrical conductivity between the source and the drain.

The memory cell MC of one embodiment of the present invention can store data even when a power supply voltage is not supplied, simply by backing up data stored in the SRAM 101 to the data memory portion 102. A previous state of the memory cell MC can be restored simply by recovering the data to the SRAM 101 by using the data stored in the memory portion 102.

FIG. 1B is a schematic diagram of a layer structure of elements. In FIG. 1B, a first layer 111 is a layer provided with Si transistors (denoted by SiFET Layer in the figure). A second layer 112 is a layer provided with a wiring layer (denoted by Wiring Layer in the figure). A third layer 113 is a layer provided with OS transistors (denoted by OSFET Layer in the figure). A fourth layer 114 is a layer provided with capacitors (denoted by Cp Layer in the figure).

In the configuration of this embodiment, the SRAM 101 and the data memory portion 102 are stacked. Specifically, the first layer 111 and the second layer 112 form a circuit configuration of the SRAM 101, and the third layer 113 and the fourth layer 114 form a circuit configuration of the data memory portion 102. Note that when the data memory portion 102 includes a Si transistor, the data memory portion 102 is preferably formed of the first layer 111, the third layer 113, and the fourth layer 114.

The SRAM 101 includes more wirings and transistors than the data memory portion 102. Therefore the layout area of the memory cell MC depends on the layout area of the SRAM 101 provided in the first layer 111 and the second layer 112. For example, in the case of a single-port SRAM, the layout area depends on the number of transistors in the first layer 111. In the case of a multiport SRAM, the layout area depends on the number of wirings in the second layer 112.

In contrast, the layout area of the memory cell MC does not increase much when the data memory portion 102 includes more transistors. By including more transistors, the data memory portion 102 can achieve stable recovery operation, higher speed operation, and simplification.

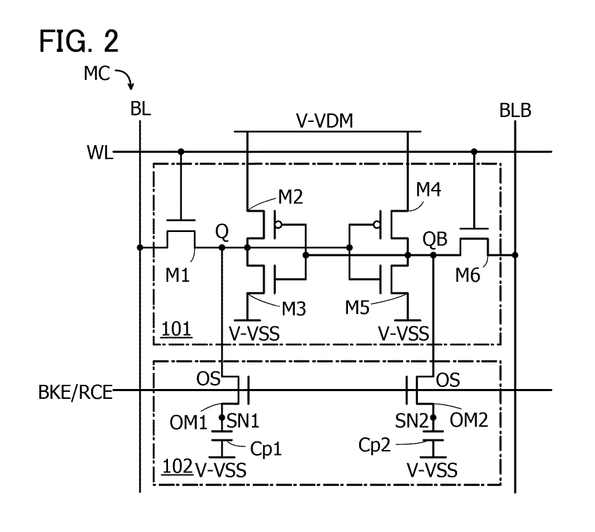

FIG. 2 illustrates a specific configuration example of the memory cell MC in FIG. 1A. The SRAM 101 illustrated in FIG. 2 includes transistors M1 to M6. The data memory portion 102 includes transistors OM1 and OM2 and capacitors Cp1 and Cp2.

In FIG. 2, a node between the transistor M1 and the transistor OM1 is denoted by Q. A node between the transistor M6 and the transistor OM2 is denoted by QB. A node between the transistor OM1 and the capacitor Cp1 is denoted by SN1. A node between the transistor OM2 and the capacitor Cp2 is denoted by SN2.

In addition, the memory cell MC is connected to wirings for supplying or controlling potentials. Examples of such wirings include a word line WL, a bit line BL, an inverted bit line BLB, the backup/recovery control line BKE/RCE, a power supply potential line V-VDM, and a power supply potential line V-VSS, as illustrated in FIG. 2.

The transistors M1 to M6 included in the SRAM 101 are Si transistors. The transistors OM1 and OM2 included in the data memory portion 102 are OS transistors.

In the above-described configuration of this embodiment, the SRAM 101 and the data memory portion 102 are stacked. The SRAM 101 includes more wirings and transistors than the data memory portion 102. Accordingly, the layout area of the memory cell MC depends on the layout area of the SRAM 101. The layout area of the memory cell MC does not increase much when more transistors are provided in the data memory portion 102. By including more transistors, the data memory portion 102 can achieve stable recovery operation, higher speed operation, and simplification.

### <Configuration Example of Memory Cell MC in Top Views and Cross-Sectional Views>

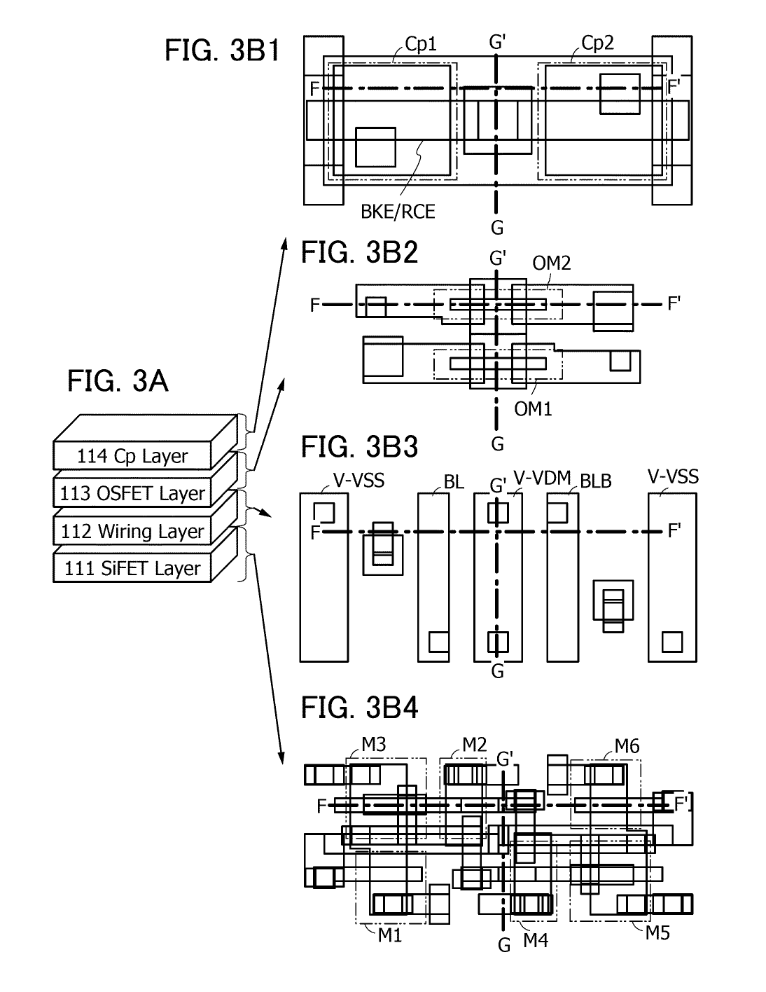

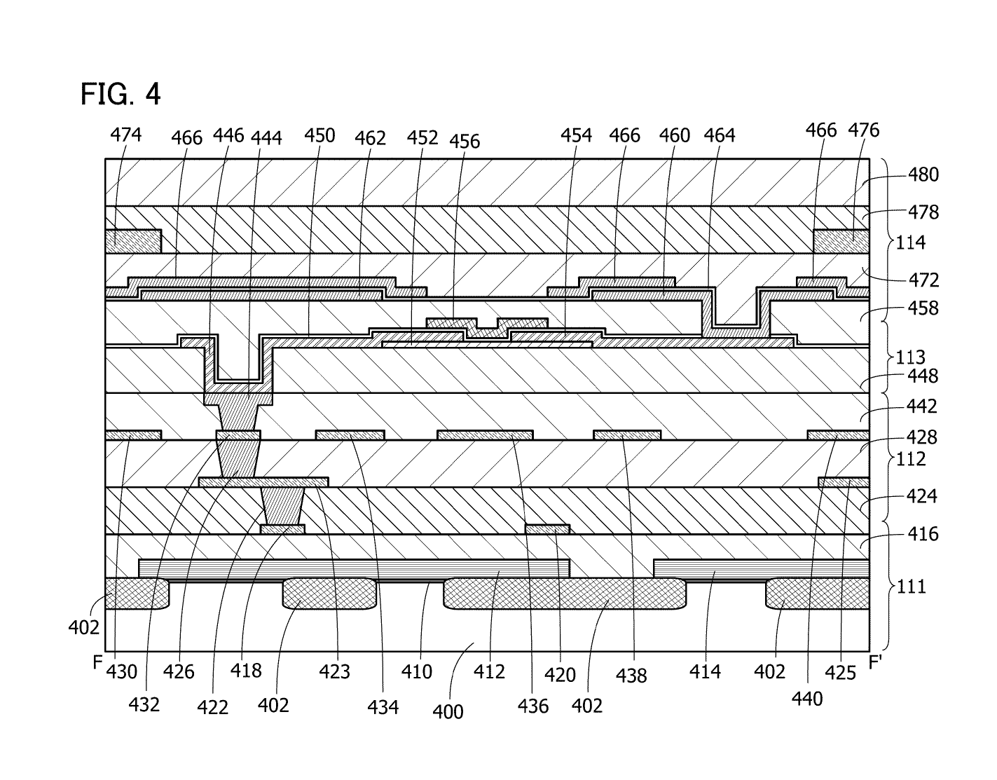

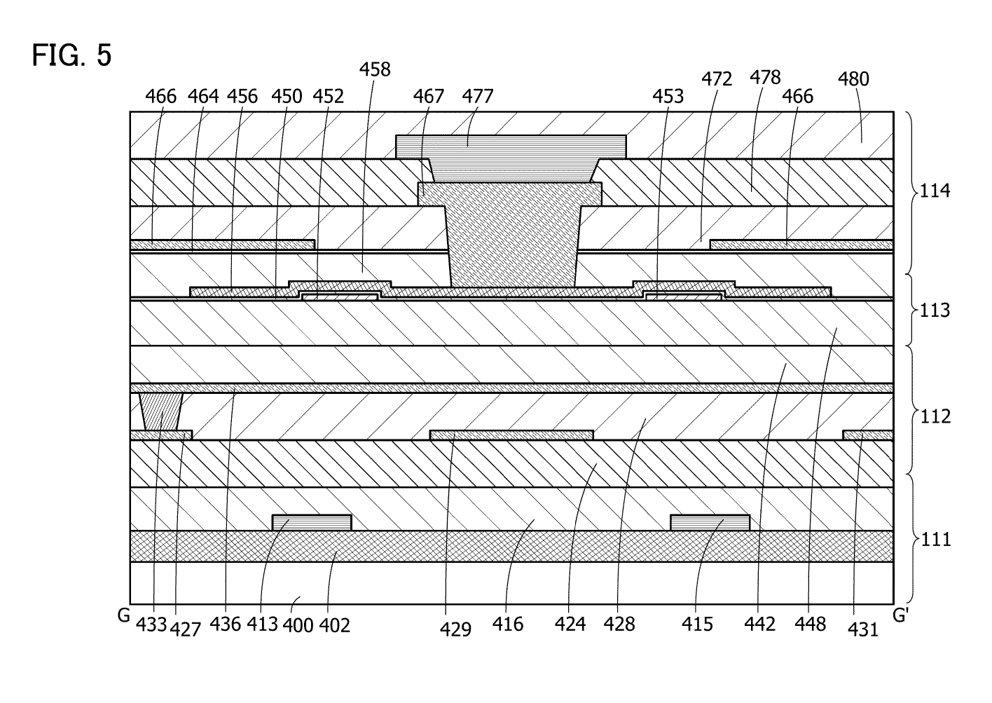

Next, an example of the memory cell MC in top views and cross-sectional views is described. Here, top views and cross-sectional views of the transistors included in the memory cell MC illustrated in FIG. 2 is described as an example with reference to FIGS. 3A to 3B4, FIG. 4, and FIG. 5.

FIG. 3A is a schematic diagram of a layer structure of elements which is the same as the structure in FIG. 1B.

FIGS. 3B1 to 3B4 are the top views corresponding to the first to fourth layers 111 to 114 in FIG. 3A.

The layout diagram of the fourth layer 114 in FIG. 3B1 corresponds to a layout diagram of the backup/recovery control line BKE/RCE and the capacitors Cp1 and Cp2.

The layout diagram of the third layer 113 in FIG. 3B2 corresponds to a layout diagram of the transistors OM1 and OM2.

The layout diagram of the second layer 112 in FIG. 3B3 corresponds to a layout diagram of the power supply potential line V-VSS, the power supply potential line V-VDM, the bit line BL, and the inverted bit line BLB.

The layout diagram of the first layer 111 in FIG. 3B4 corresponds to a layout diagram of the transistors M1 to M6.

In the configuration in FIGS. 3B1 to 3B4, the SRAM 101 is formed of the Si transistors, i.e., the transistors M1 to M6, which are included in the first layer 111, and the power supply potential line V-VSS, the power supply potential line V-VDM, the bit line BL, and the inverted bit line BLB which are included in the second layer 112. In addition, the data memory portion is formed of the OS transistors, i.e., the transistors OM1 and OM2, which are included in the third layer 113, and the backup/recovery control line BKE/RCE, and the capacitors Cp1 and Cp2 which are included in the fourth layer 114.

A source or a drain of each of the transistors M1 to M6 in the first layer 111 overlaps with a wiring in the second layer 112. The transistors M1 to M6 in the first layer 111 are electrically connected to the wirings in the second layer 112 through opening portions.

The transistors M1 to M6 in the first layer 111 are electrically connected to the transistors OM1 and OM2 in the third layer 113 through the second layer 112. A source or a drain of each of the transistors OM1 and OM2 in the third layer 113 overlaps with a wiring in the second layer 112. The transistors OM1 and OM2 in the third layer 113 are electrically connected to the transistors M1 to M6 in the first layer 111 through the wirings in the second layer 112.

The transistors OM1 and OM2 in the third layer 113 are electrically connected to the capacitors Cp1 and Cp2. The sources or drains of the transistors OM1 and OM2 in the third layer 113 overlap with electrodes of the capacitors Cp1 and Cp2 in the fourth layer 114. The electrode of the capacitor Cp1 and the electrode of the capacitor Cp2 in the fourth layer 114 are electrically connected to the source or drain of the transistor OM1 and the source or drain of the transistor OM2, respectively, in the third layer 113 through opening portions.

With the configuration illustrated in FIGS. 3A to 3B4, the memory cell MC can achieve a layout which enables backup or recovery of data without an increase in area compared to an SRAM including six transistors. Accordingly, the semiconductor device including the memory cell MC can be reduced in size.

Although the memory cell MC employing a single-port SRAM is given as an example in the configuration in FIGS. 3A to 3B4, one embodiment of the present invention is particularly effective when it is applied to a memory cell MC employing a multiport SRAM.

The multiport SRAM includes more wirings and transistors for controlling writing and reading of data. In one embodiment of the present invention, the transistors of the data memory portion 102 are provided over the wirings and transistors of the SRAM 101. An increase in the layout area of the SRAM 101 is specifically an increase in the layout area of the first layer 111 and the second layer 112.

The increase in layout area is mainly attributed to an increase in the number of wirings in the second layer 112 due to an increase in the number of ports. The layout area of the SRAM 101 increases in proportion to the square of the number of ports. An increase in the area of the second layer 112 increases the area of the first layer 111, the third layer 113, and the fourth layer 114.

The first layer 111, the third layer 113, and the fourth layer 114, which are stacked with the second layer 112, occupy the same layout area as the second layer 112 but include fewer wirings than the second layer 112. Therefore the first layer 111, the third layer 113, and the fourth layer 114 can include an additional transistor without an increase in layout area. The first layer 111, the third layer 113, and the fourth layer 114 can include a transistor and a wiring forming the data memory portion 102.

A wiring and a transistor added to the data memory portion 102 can lead to a speed-up of its operation. For example, a transistor added to the same layer as the first layer 111 can serve as one of the transistors in the data memory portion 102. When this transistor provided in the same layer as the first layer 111 functions as an inverter, the data memory portion 102 can perform static data recovery. The data memory portion 102 capable of static data recovery can operate at higher speed.

FIG. 4 is a cross-sectional view taken along dashed-dotted line F-F′ in FIGS. 3 A to 3B4, and FIG. 5 is a cross-sectional view taken along dashed-dotted line G-G′ in FIGS. 3A to 3B4.

FIG. 4 illustrates a semiconductor substrate 400, element isolation insulating films 402, a gate insulating layer 410, a gate electrode 412, a gate electrode 414, an interlayer insulating layer 416, a wiring layer 418, a wiring layer 420, a conductive layer 422, an interlayer insulating layer 424, a wiring layer 423, a wiring layer 425, a conductive layer 426, an interlayer insulating layer 428, an interlayer insulating layer 442, a wiring layer 430, a wiring layer 432, a wiring layer 434, a wiring layer 436, a wiring layer 438, a wiring layer 440, a conductive layer 444, a wiring layer 446, an interlayer insulating layer 448, a semiconductor layer 452, a gate insulating layer 450, a wiring layer 454, a gate electrode 456, an interlayer insulating layer 458, a conductive layer 460, a conductive layer 462, an insulating layer 464, conductive layers 466, an interlayer insulating layer 472, a wiring layer 474, a wiring layer 476, an interlayer insulating layer 478, and an interlayer insulating layer 480.

FIG. 5 illustrates the semiconductor substrate 400, the element isolation insulating film 402, a gate electrode 413, a gate electrode 415, the interlayer insulating layer 416, the interlayer insulating layer 424, a wiring layer 427, a wiring layer 429, a wiring layer 431, a conductive layer 433, the interlayer insulating layer 428, the wiring layer 436, the interlayer insulating layer 442, the interlayer insulating layer 448, the semiconductor layer 452, a semiconductor layer 453, the gate insulating layer 450, the gate electrode 456, the interlayer insulating layer 458, the insulating layer 464, the conductive layer 466, the interlayer insulating layer 472, the interlayer insulating layer 478, a conductive layer 467, a wiring layer 477, and the interlayer insulating layer 480.

The semiconductor substrate 400 can be, a silicon substrate having n-type or p-type conductivity, a germanium substrate, a silicon germanium substrate, a compound semiconductor substrate (e.g., a GaAs substrate, an InP substrate, a GaN substrate, a SiC substrate, a GaP substrate, a GaInAsP substrate, or a ZnSe substrate), or the like.

The transistors in the first layer 111 are electrically isolated from another transistor by the element isolation insulating films 402. The element isolation insulating film 402 can be formed by a local oxidation of silicon (LOCOS) method, a trench isolation method, or the like.

The gate insulating layer 410 is formed in such a manner that a surface of the semiconductor substrate 400 is oxidized by heat treatment, so that a silicon oxide film is formed, and then the silicon oxide film is selectively etched. Alternatively, the gate insulating layer 410 is formed in such a manner that silicon oxide, silicon oxynitride, a metal oxide such as hafnium oxide, which is a high dielectric constant material (also referred to as a high-k material), or the like is formed by a CVD method, a sputtering method, or the like and then is selectively etched.

The gate electrodes 412, 413, 414, 415, and 456, the wiring layers 418, 420, 423, 427, 429, 430, 431, 432, 434, 436, 438, 440, 446, 454, 474, 476, and 477, and the conductive layers 422, 426, 433, 444, 460, 462, 466, and 467 are each preferably formed using a metal material such as aluminum, copper, titanium, tantalum, or tungsten. Alternatively, polycrystalline silicon to which an impurity such as phosphorus is added can be used. As the formation method, any of a variety of film formation methods such as an evaporation method, a PE-CVD method, a sputtering method, and a spin coating method can be used.

The interlayer insulating layers 416, 424, 428, 442, 448, 458, 472, 478, and 480 and the insulating layer 464 are each preferably a single layer or a multilayer formed using an inorganic insulating layer or an organic insulating layer. The inorganic insulating layer preferably has a single-layer structure or a layered structure including any of a silicon nitride film, a silicon oxynitride film, a silicon nitride oxide film, and the like. The organic insulating layer is preferably a single layer or a multilayer formed using polyimide, acrylic, or the like. There is no particular limitation on a method of forming each insulating layer; for example, a sputtering method, an MBE method, a PE-CVD method, a pulsed laser deposition method, an ALD method, or the like can be employed as appropriate.

The semiconductor layers 452 and 453 can each be a single layer or a stacked layer formed using an oxide semiconductor. The oxide semiconductor is an oxide containing at least indium, gallium, and zinc, such as an In—Ga—Zn-based oxide (also referred to as IGZO). Note that the In—Ga—Zn-based oxide means an oxide containing In, Ga, and Zn, and may contain a metal element other than In, Ga, and Zn. For example, it is possible to use an In—Sn—Ga—Zn-based oxide, an In—Hf—Ga—Zn-based oxide, or an In—Al—Ga—Zn-based oxide. The oxide semiconductor can be formed by a sputtering method, an atomic layer deposition (ALD) method, an evaporation method, a coating method, or the like.

The gate insulating layer 450 is preferably a single layer or a multilayer formed using an inorganic insulating layer. The gate insulating layer 450 preferably has an effect of supplying oxygen to the semiconductor layers 452 and 453.

With the structure in FIG. 4 and FIG. 5, the power supply potential line V-VDM and channel formation regions of the transistors OM1 and OM2 can be stacked in the memory cell MC. In the case where the power supply voltage is supplied to the memory cell MC, the power supply potential of the power supply potential line V-VDM is set to a high power supply potential. In that case, with the use of the power supply potential line V-VDM (wiring layer 436 in FIG. 4) as back gates of the transistors OM1 and OM2, on-state currents of the transistors OM1 and OM2 can be increased. In contrast, in the case where the power supply voltage is not supplied to the semiconductor device, the power supply potential of the power supply potential line V-VDM is set to a low power supply potential. In that case, with the use of the power supply potential line V-VDM as the back gates of the transistors OM1 and OM2, a feature such as low off-state currents of the transistors OM1 and OM2 is not adversely affected. Thus, the on-state currents of the transistors OM1 and OM2 can be increased and the off-state currents thereof can be kept low.

### <Operation of Memory Cell MC>

Next, operation of the memory cell MC is described.

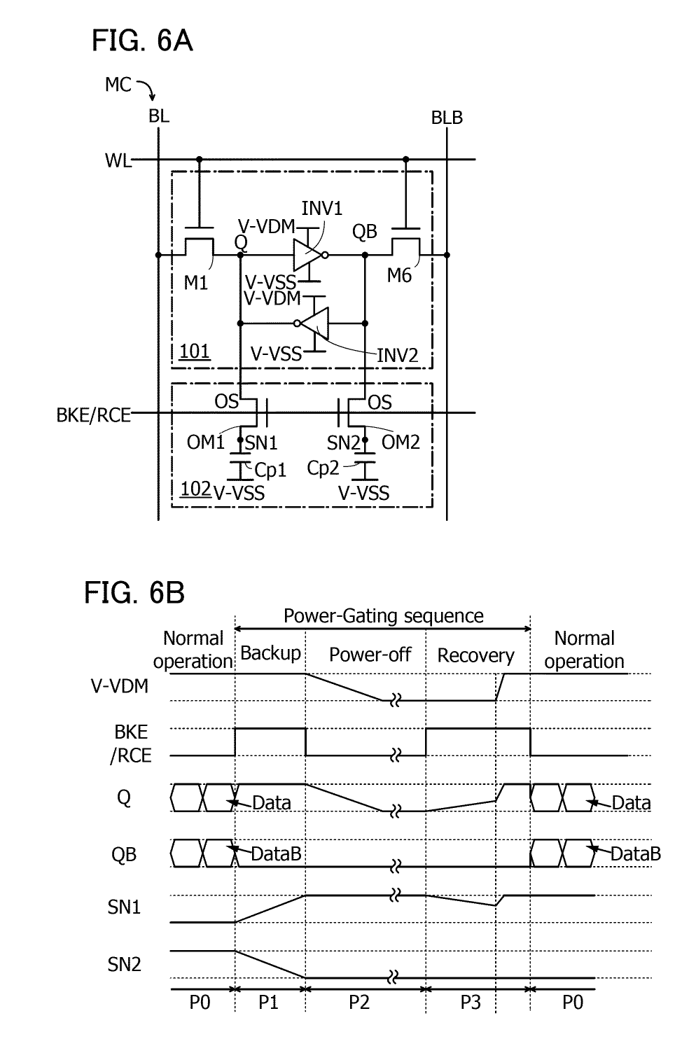

FIG. 6A is a circuit diagram in which the transistors M2 to M5 in the memory cell MC illustrated in FIG. 2 are replaced with inverters INV1 and INV2.

Operation of the memory cell MC illustrated in FIG. 6A is described using a timing chart in FIG. 6B. In FIG. 6B, a power-gating sequence (PG sequence) of backup (Backup), stop of supply of a power supply voltage (Power-off), and recovery (Recovery) is illustrated.

According to the timing chart in FIG. 6B, data Data and data DataB are first held at the nodes Q and QB in normal operation (Normal operation), respectively. Note that in FIG. 6B, the data Data is at an H-level potential and the data DataB is at an L-level potential.

In backup, first, the potential of the backup/recovery control line BKE/RCE is set to H level so that the transistors OM1 and OM2 are turned on. Then, the nodes SN1 and SN2 have the same potential as the nodes Q and QB, respectively, so that backup to the nodes SN1 and SN2 is performed. Note that in FIG. 6B, an H-level potential is held at the node SN1 and an L-level potential is held at the node SN2.

After the backup operation is finished, supply of the power supply voltages is stopped. In other words, the potential of the power supply potential line V-VDM is set equal to the potential of the power supply potential line V-VSS, i.e., L level. As the potential of the power supply potential line V-VDM decreases, the potentials of the nodes Q and QB also decrease. In contrast, when the potential of the backup/recovery control line BKE/RCE is set to L level, the potentials of the nodes SN1 and SN2 are held.

In recovery, first, the potential of the backup/recovery control line BKE/RCE is set to H level so that the transistors OM1 and OM2 are turned on. Then, the nodes SN1 and SN2 have the same potential as the nodes Q and QB, respectively. Consequently, a potential difference between the node Q and the node QB is generated. In the state where the potential difference is generated, the potential of the power supply potential line V-VDM is set to H level. Then, the potentials of the nodes Q and QB are returned to those in normal operation.

Through the above-described PG sequence, normal operation can be restarted. Furthermore, although power gating of the memory cell MC is performed, loss of data stored in the SRAM 101 can be prevented.

### <Configuration Examples of SRAM 101>

Next, configuration examples of the SRAM 101 are described.

The single-port SRAM is described as an example above with reference to FIG. 2, FIG. 3A, and FIG. 6B. One embodiment of the present invention is not limited to the single-port SRAM and preferably applied to a multiport SRAM.

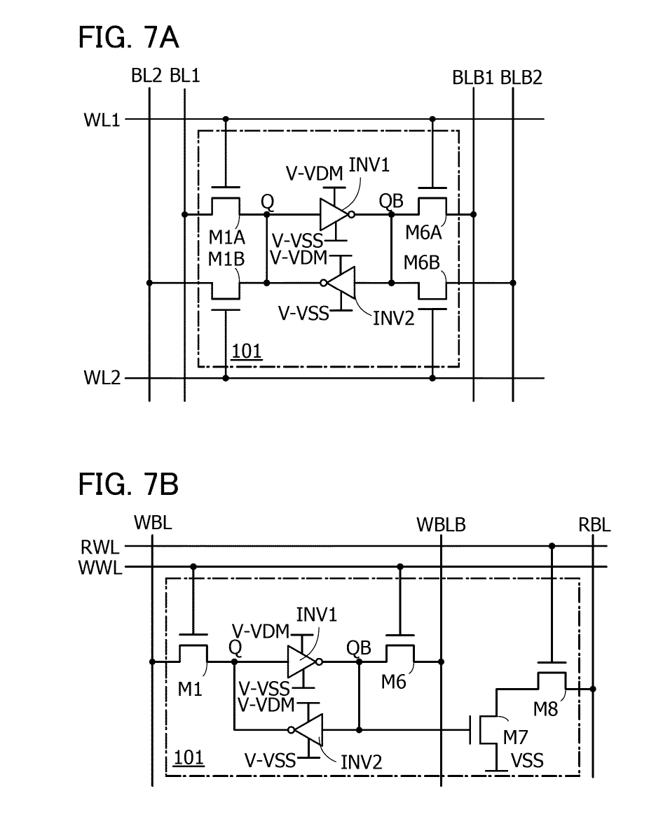

An example of a multiport SRAM which can be used as the SRAM 101 is illustrated in FIG. 7A.

FIG. 7A illustrates the SRAM 101 including transistors M1A, M1B, M6A, and M6B, the inverters INV1 and INV2, bit lines BL1, BLB1, BL2, and BLB2, and word lines WL1 and WL2.

An example of another multiport SRAM which can be used as the SRAM 101 is illustrated in FIG. 7B.

FIG. 7B illustrates the SRAM 101 including transistors M1, M6, M7, and M8, the inverters INV1 and INV2, write bit lines WBL and WBLB, a read bit line RBL, a write word line WWL, and a read word line RWL.

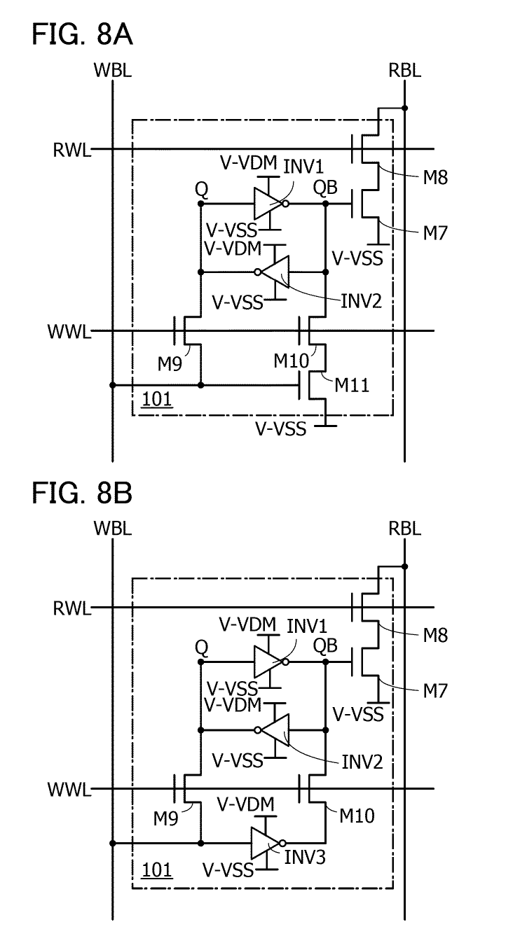

An example of another multiport SRAM which can be used as the SRAM 101 is illustrated in FIG. 8A.

FIG. 8A illustrates the SRAM 101 including transistors M7, M8, M9, M10, and M11, the inverters INV1 and INV2, a write bit line WBL, a read bit line RBL, a write word line WWL, and a read word line RWL.

An example of another multiport SRAM which can be used as the SRAM 101 is illustrated in FIG. 8B.

FIG. 8B illustrates the SRAM 101 including transistors M7, M8, M9, and M10, inverters INV1, INV2, and INV3, a write bit line WBL, a read bit line RBL, a write word line WWL, and a read word line RWL.

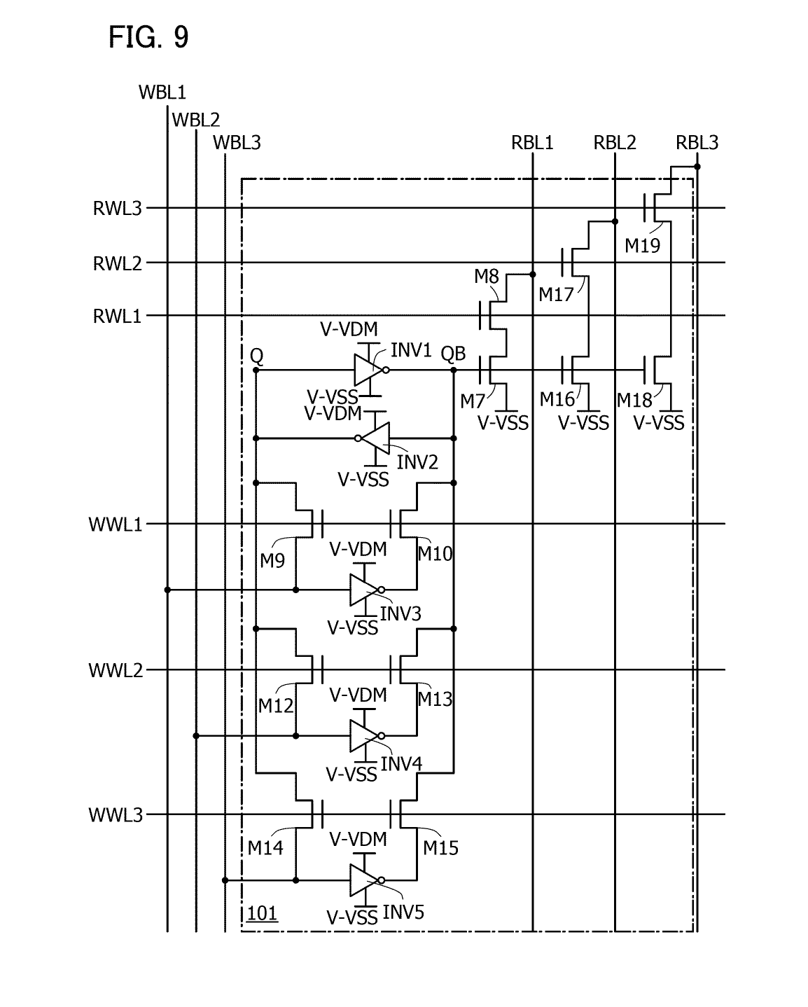

An example of another multiport SRAM which can be used as the SRAM 101 is illustrated in FIG. 9.

FIG. 9 illustrates the SRAM 101 including transistors M7, M8, M9, M10, M12 to M19, inverters INV1 to INV5, write bit lines WBL1 to WBL3, read bit lines RBL1 to RBL3, write word lines WWL1 to WWL3, and read word lines RWL1 to RWL3.

The multiport SRAM in each of FIGS. 7A and 7B, FIGS. 8A and 8B, and FIG. 9 includes more transistors and more wirings than the single-port SRAM. The layout area of the multiport SRAM increases in proportion to the square of the number of ports.

In the SRAM 101, as the layout area, particularly of the layer provided with the wirings, increases, another layer provided with the transistors and the like generates a larger extra region. Hence even when the data memory portion 102 includes more transistors, an area overhead can be zero or substantially negligible.

### <Configuration Examples of Data Memory Portion 102>

Next, configuration examples of the data memory portion 102 are described.

The circuit configuration for dynamic data recovery using the transistors OM1 and OM2 and the capacitors Cp1 and Cp2 is described as an example above with reference to FIG. 2, FIG. 3A, and FIG. 6B. One embodiment of the present invention is not limited to the circuit configuration for dynamic data recovery and preferably applied to a circuit configuration for static data recovery.

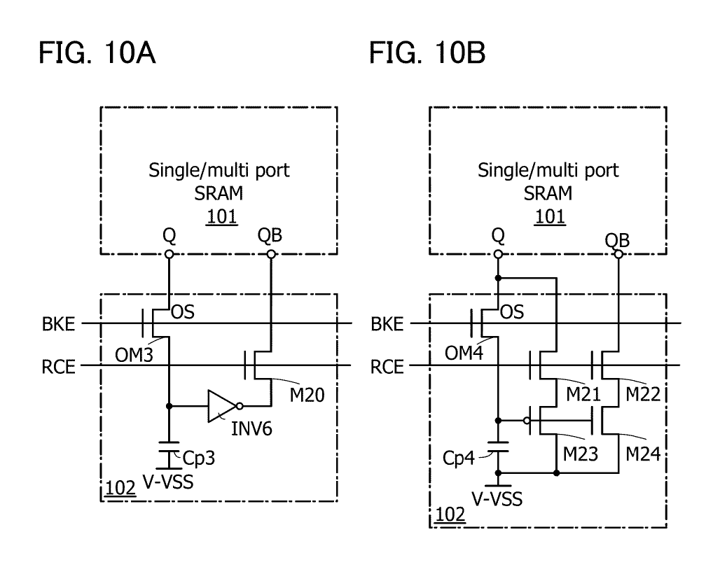

An example of a circuit configuration of the data memory portion 102 for static data recovery is illustrated in FIG. 10A.

FIG. 10A illustrates the data memory portion 102 including a transistor OM3, a transistor M20, a capacitor Cp3, an inverter INV6, a backup control line BKE, and a recovery control line RCE.

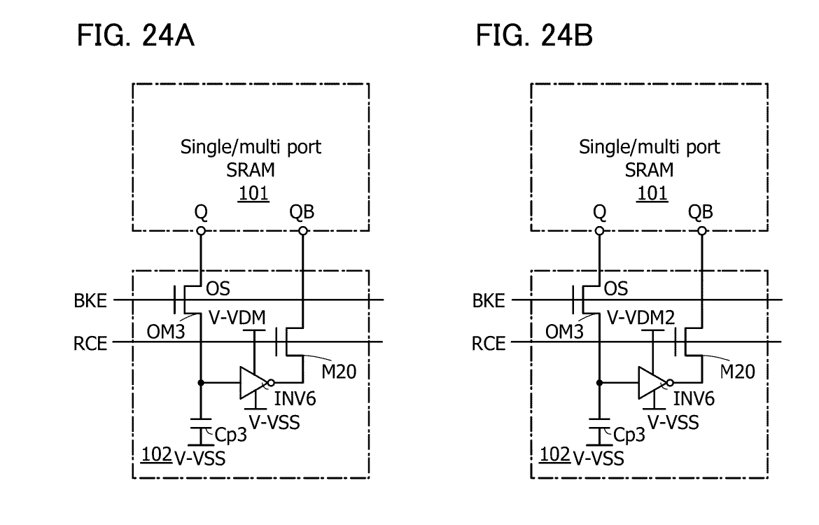

Note that a power supply voltage supplied to the inverter INV6 may be the same as in the SRAM 101 as illustrated in FIG. 24A, or may be a power supply voltage (VDM2/VSS) which is different from that in the SRAM 101 as illustrated in FIG. 24B.

Another example of a circuit configuration of the data memory portion 102 for static data recovery is illustrated in FIG. 10B.

FIG. 10B illustrates the data memory portion 102 including a transistor OM4, transistors M21 to M24, a capacitor Cp4, the backup control line BKE, and the recovery control line RCE.

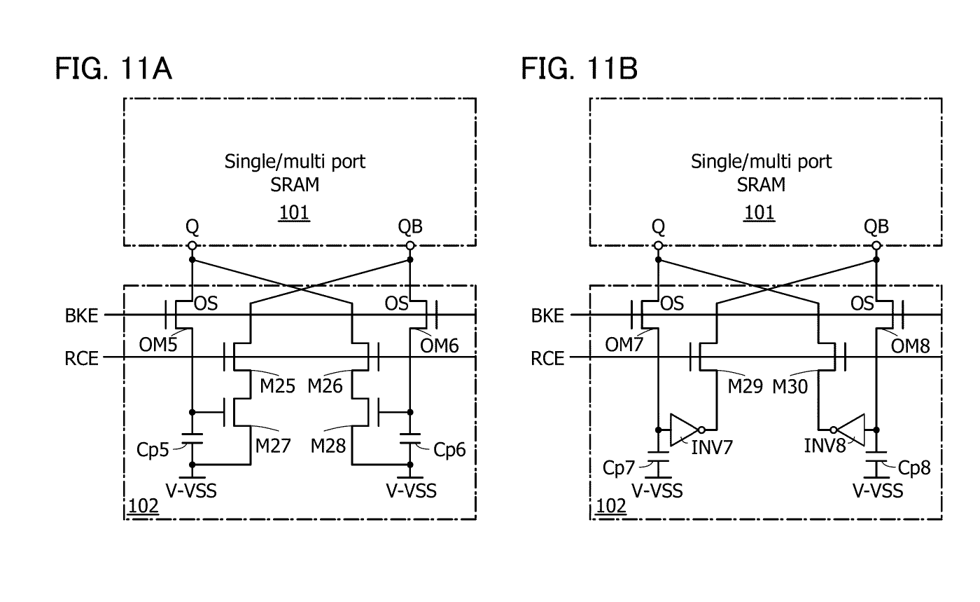

Another example of a circuit configuration of the data memory portion 102 for static data recovery is illustrated in FIG. 11A.

FIG. 11A illustrates the data memory portion 102 including transistors OM5 and OM6, transistors M25 to M28, capacitors Cp5 and Cp6, the backup control line BKE, and the recovery control line RCE.

Another example of a circuit configuration of the data memory portion 102 for static data recovery is illustrated in FIG. 11B.

FIG. 11B illustrates the data memory portion 102 including transistors OM7 and OM8, transistors M29 and M30, capacitors Cp1 and Cp8, inverters INV7 and INV8, the backup control line BKE, and the recovery control line RCE.

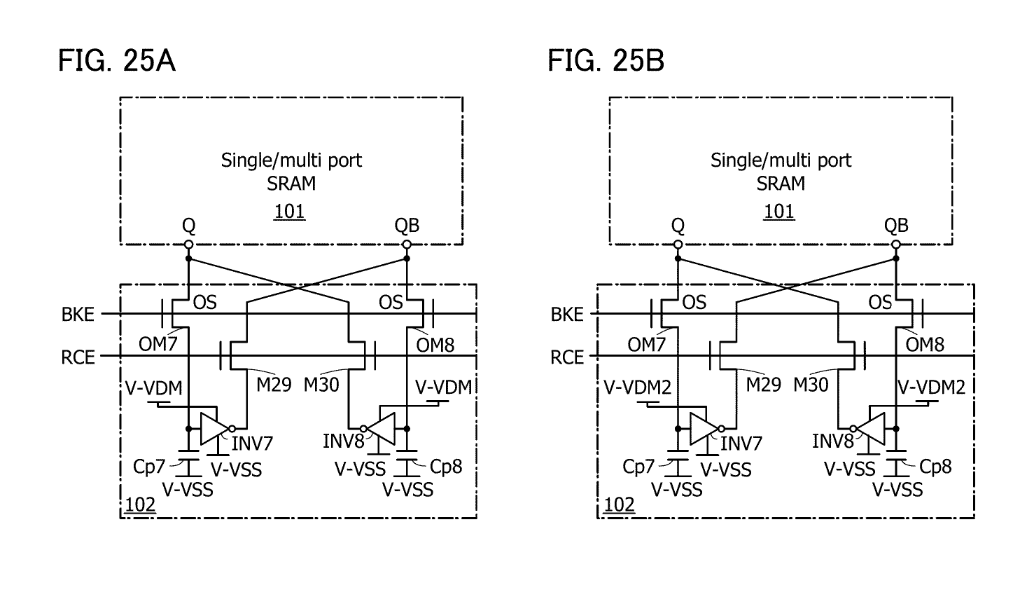

Note that a power supply voltage supplied to the inverters INV7 and INV8 may be the same as in the SRAM 101 as illustrated in FIG. 25A, or may be a power supply voltage (VDM2/VSS) which is different from that in the SRAM 101 as illustrated in FIG. 25B.

As described above, the multiport SRAM includes more wirings than the single-port SRAM. Accordingly, the layout area of the second layer 112 which is a wiring layer increases. In contrast, a larger extra region is formed in the first layer 111, the third layer 113, and the fourth layer 114. Hence, even when the data memory portion 102 includes more transistors as illustrated in FIGS. 10A and 10B and FIGS. 11A and 11B, an area overhead can be zero or substantially negligible.

Thus, the number of transistors in the data memory portion 102 can be increased so that the data memory portion can be a static memory. Data held in the static data memory portion can be read without being destroyed.

When the data memory portion 102 is a static data memory portion, stable data recovery can be achieved and the recovery can be simplified and speeded up.

In the data memory portion 102 which is a static memory illustrated in FIGS. 10A and 10B and FIGS. 11A and 11B, data can be read even when the capacitance of the capacitor is smaller than in a dynamic memory. In this case, the OS transistors in the third layer 113 and the capacitors in the fourth layer 114 may be provided in the same layer. In such a structure, the number of process steps and manufacturing cost can be reduced.

In the above-described configuration of this embodiment, the SRAM 101 and the data memory portion 102 are stacked. The multiport SRAM 101 includes more wirings and transistors. Hence an increase in the number of transistors in the data memory portion 102 does not increase the layout area. An increase in the number of transistors in the data memory portion 102 enables static operation. Thus, the data memory portion 102 can achieve stable recovery operation, higher speed operation, and simplification.

Note that the example in which an oxide semiconductor is used for the transistor 103 is described above as one embodiment of the present invention; one embodiment of the present invention is not limited thereto. Depending on the case, the transistor 103, for example, can be a transistor that does not include an oxide semiconductor as long as the transistor has a low off-state current. For example, as the transistor 103, a transistor including a semiconductor having a wide band gap may be used in one embodiment of the present invention.

This embodiment can be implemented in appropriate combinations with any of the other embodiments.

### Embodiment 2

In this embodiment, an example of the operation different from that of the memory cell MC described in the above embodiment is described.

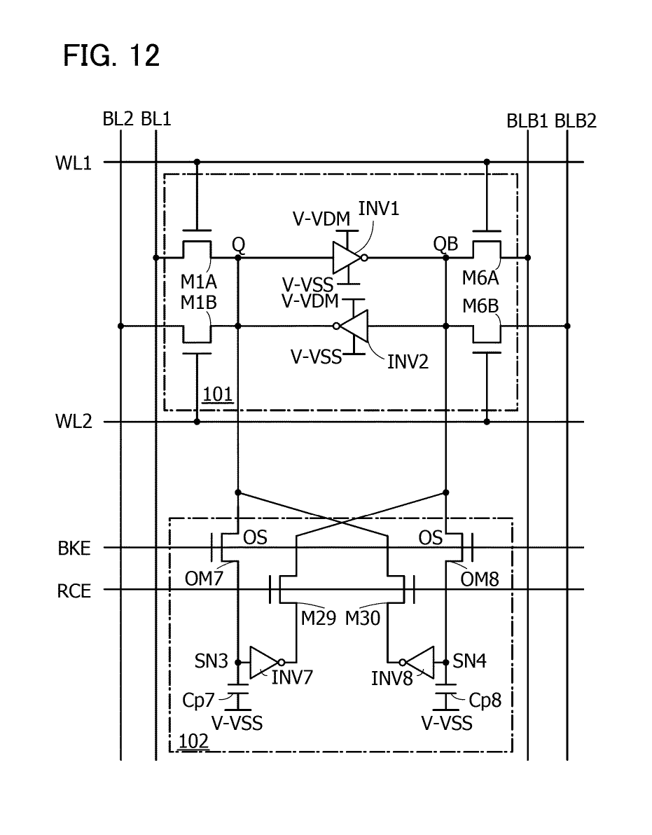

In this embodiment, operation of the memory cell MC illustrated in FIG. 12 is described. The memory cell MC illustrated in FIG. 12 includes the multiport SRAM 101 in FIG. 7A and the data memory portion 102 in FIG. 11B for static data recovery.

Note that in FIG. 12, nodes holding charge corresponding to data in the data memory portion 102 are denoted by SN3 and SN4.

Note that a power supply voltage supplied to the inverters INV7 and INV8 in FIG. 12 may be the same as in the SRAM 101 as illustrated in FIG. 25A, or may be a power supply voltage (VDM2/VSS) which is different from that in the SRAM 101 as illustrated in FIG. 25B.

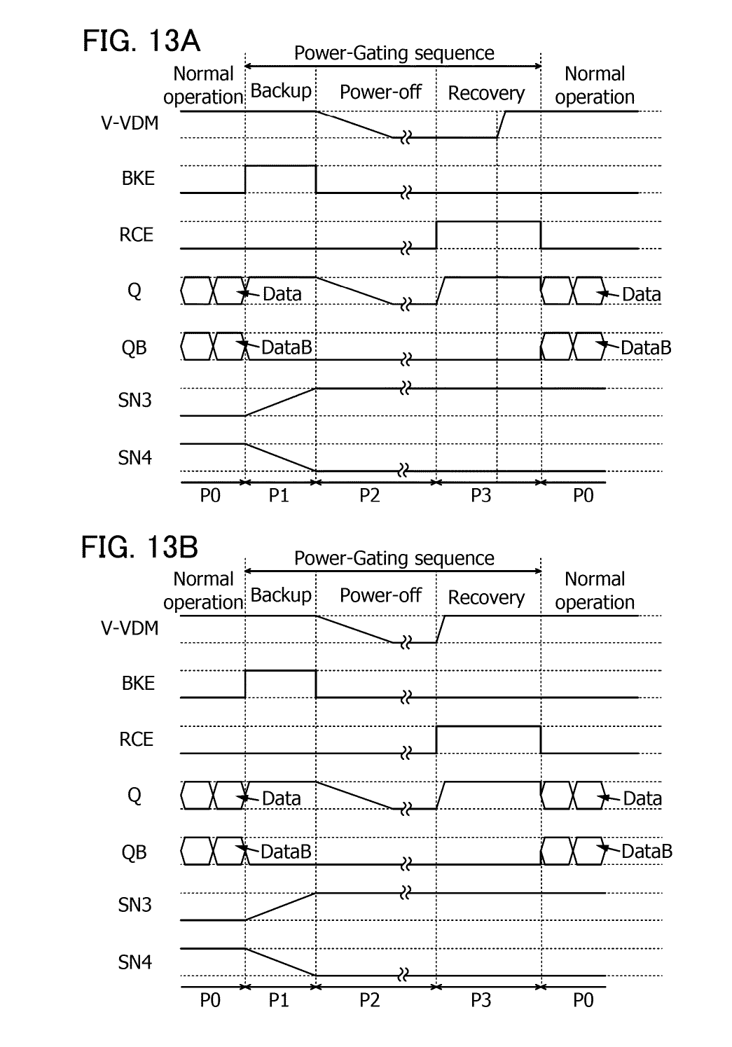

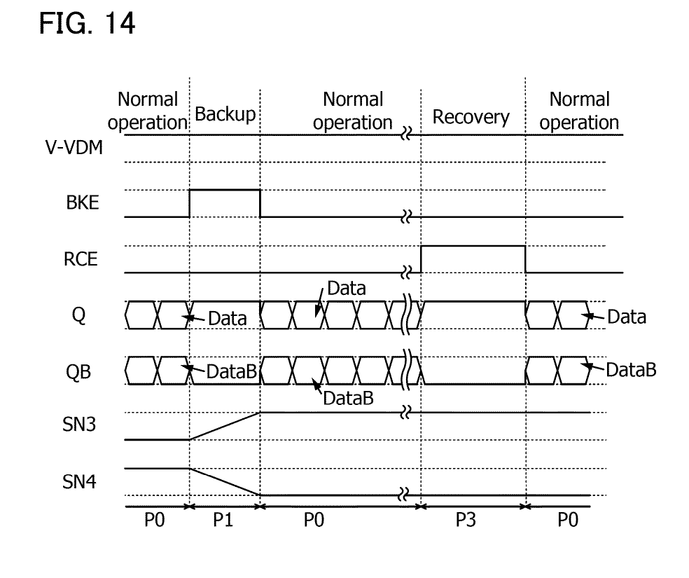

FIGS. 13A and 13B and FIG. 14 are timing charts different from that of the operation of the memory cell MC illustrated in FIG. 12. FIGS. 13A and 13B illustrate operation of the power supply potential line V-VDM, the backup control line BKE, and the recovery control line RCE in recovery, which is different from that in FIG. 6B.

According to the timing chart illustrated in FIG. 13A, the potential of the recovery control line RCE is set to H level first in recovery. Then, in accordance with charge held in the nodes SN3 and SN4, a potential difference between the nodes Q and QB is generated. In the state where the potential difference is generated, the potential of the power supply potential line V-VDM is set to H level. Then, the potentials of the nodes Q and QB are returned to those in normal operation.

According to FIG. 13A, the potential difference between the nodes Q and QB can be increased. Thus, even a variation in the potentials of the nodes Q and QB due to noise or the like results in fewer malfunctions, and stable recovery operation can be performed.

Through the above-described PG sequence, normal operation can be restarted. Furthermore, although power gating of the memory cell MC is performed, loss of data stored in the SRAM 101 can be prevented.

Alternatively, the memory cell MC illustrated in FIG. 12 can be operated according to the timing chart in FIG. 13B. As in FIG. 13B, in recovery, the potential of the recovery control line RCE is set to H level and the potential of the power supply potential line V-VDM is also set to H level. Consequently, the recovery can be simplified and speeded up.

The memory cell MC illustrated in FIG. 12 can perform static data recovery. Thus, original data held in the data memory portion 102 can be recovered without being destroyed.

FIG. 14 is a timing chart of operation employing static data recovery. According to the timing chart in FIG. 14, backup or recovery can be performed during normal operation. For example, data in the SRAM 101 in normal operation can be backed up to the data memory portion 102 and recovered as necessary. The recovery does not destroy data held in the nodes SN3 and SN4.

Thus, according to the recovery operation in FIG. 14, data held in the memory cell MC can be restored to the previous state easily. The operation can be applied to branch prediction in a pipeline processing or to a debugging operation, for example.

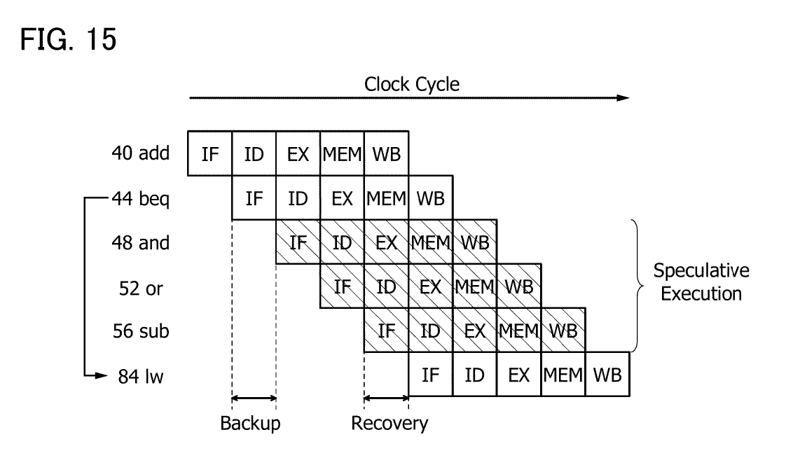

An example of operation in which the backup or recovery illustrated in FIG. 14 is applied to branch prediction of a pipeline processing so that data can be restored to the previous state is shown in FIG. 15.

FIG. 15 illustrates a configuration of a five-stage pipeline processing. Examples of the instructions are “add (addition)”, “beq (conditional branch)”, “and (logical product)”, “or (logical sum)”, “sub (subtraction)”, and “lw (memory reading). Numerals given to the instructions denote the addresses thereof. The instructions illustrated in FIG. 15 are an instruction set of the MIPS architecture. The instructions in a single cycle are fetched (IF), decode (ID), execution (EX), memory access (MEM), and write back (WB), for example.

In the example of the operation illustrated in FIG. 15, branch prediction is performed by the instruction “beq (conditional branch)”. In the branch prediction, even if the branch is not taken, the instructions (hatched instructions in the figure) are speculatively executed until the cycle in which memory access (MEM) is performed. The branch prediction can speed up the operation.

The data backup illustrated in FIG. 14 is performed in the cycle in which the instruction “beq (conditional branch)” is fetched. The data recovery illustrated in FIG. 14 is performed before a jump to the instruction “lw (memory reading)”. By the backup and recovery, data can be restored to the state before the branch prediction. Therefore re-execution of the instructions becomes unnecessary, and the operation can be speeded up accordingly.

As described in this embodiment, in the memory cell of one embodiment of the present invention, stable data recovery can be achieved and the recovery can be simplified and speeded up. Furthermore, the memory cell of one embodiment of the present invention can be applied to branch prediction or debugging because of the simplified backup and recovery of data.

This embodiment can be implemented in appropriate combinations with any of the other embodiments.

### Embodiment 3

In this embodiment, configurations of block diagrams of a cache including the memory cell MC illustrated in FIGS. 1A and 1B and circuits accessing the cache are described.

### <Specific Example of Cache>

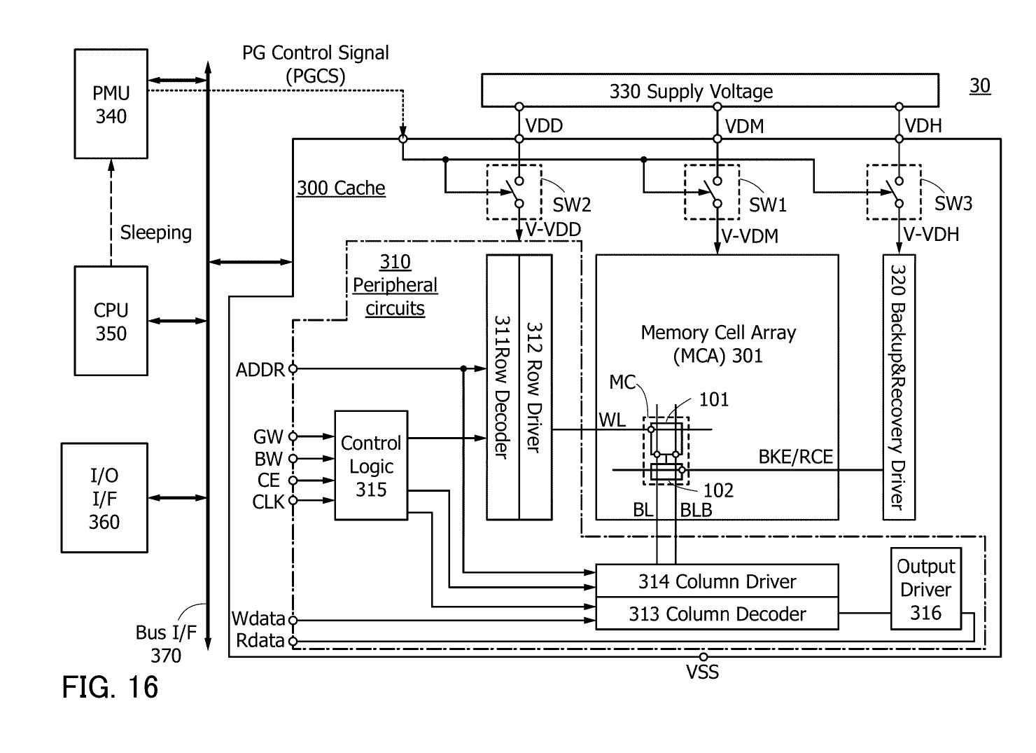

A semiconductor device 30 includes a cache 300 (denoted by Cache), a power supply voltage supplying circuit 330 (denoted by Supply Voltage), a power management unit 340 (denoted by PMU), a CPU 350, an input/output interface 360 (denoted by I/O UF), and a bus interface 370 (denoted by Bus UF), as shown in FIG. 16.

The power management unit 340 has a function of performing power gating of the circuits included in the cache 300. The power management unit 340 outputs a power gating control signal (PGCS). Thus, the power consumption of the semiconductor device 30 can be reduced.

The power management unit 340 performs power gating in accordance with a sleeping signal (denoted by Sleeping) from the CPU 350, a signal from external hardware through the input/output interface 360, or a state of the bus interface 370.

The cache 300 includes a memory cell array 301 (denoted by MCA), peripheral circuits 310 (denoted by Peripheral Circuits), a backup/recovery driver circuit 320 (denoted by Backup & Recovery Driver), and power switches SW1 to SW3.

The cache 300 is a device having a function of temporarily storing an instruction used in the CPU 350 or data such as arithmetic results, and is also referred to as a memory device.

Components included in the cache 300 will be described.

The memory cell array 301 includes the memory cell MC described in the above embodiments. The memory cell MC includes the SRAM 101 and the data memory portion 102.

In the SRAM 101, data writing/reading is controlled by the word line WL, the bit line BL, and the inverted bit line BLB. For details of the SRAM 101 and the data memory portion 102, refer to the descriptions in the above embodiments.

The peripheral circuits 310 include a row decoder 311, a row driver 312, a column decoder 313, a column driver 314, a driver control logic circuit 315, and an output driver 316.

An address signal ADDR and a control signal from the driver control logic circuit 315 are supplied to the row decoder 311 and the row driver 312. The row decoder 311 and the row driver 312 are a circuit having a function of generating a signal supplied to the word line WL, for example, a word signal. Note that the number of row decoders 311 and row drivers 312 can be determined in accordance with the number of word lines WL or of read word lines RWL or write word lines WWL described in the above embodiment.

An address signal ADDR and a control signal from the driver control logic circuit 315 are supplied to the column decoder 313 and the column driver 314. The column decoder 313 and the column driver 314 are a circuit having a function of generating a signal supplied to the bit line BL and the inverted bit line BLB, e.g., a precharge signal and a function of supplying written data Wdata to be input to the bit line BL and the inverted bit line BLB. The column decoder 313 and the column driver 314 include a sense amplifier and are a circuit having a function of outputting a signal read from the memory cell array 301 to the output driver 316. Note that the number of column decoders 313 and column drivers 314 can be determined in accordance with the number of bit lines BL or inverted bit lines BLB or of read bit lines RBL or write bit lines WBL described in the above embodiment.

The driver control logic circuit 315 is a circuit having a function of generating control signals for controlling the row decoder 311, the row driver 312, the column decoder 313, and the column driver 314 in accordance with a global write signal (GW), a byte write signal (BW), a chip enable signal (CE), and a clock signal (CLK) which are input.

The output driver 316 is a circuit having a function of generating read data Rdata on the basis of data obtained by the column decoder 313 and the column driver 314 and outputting the read data Rdata to an external device.

The backup/recovery driver circuit 320 is connected to the backup/recovery control line BKE/RCE. The backup/recovery driver circuit 320 has a function of supplying a signal for data backup and recovery between the SRAM 101 and the data memory portion 102. As the backup/recovery control line BKE/RCE, a backup control line BKE and a recovery control line RCE may be separately provided.

The power switches SW1 to SW3 can switch whether the power supply potentials VDM, VDD, and VDH generated from the power supply voltage supplying circuit 330 are supplied to the memory cell array 301, the peripheral circuit 310, and the backup/recovery driver circuit 320. The power switches SW1 to SW3 are switched by the power gating control signal.

When the power switch SW1 is turned off, the potential of the power supply potential line V-VDM which supplies a power supply potential to the memory cell array 301 becomes equal to the potential of the power supply potential line V-VSS. When the power switch SW2 is turned off, the potential of the power supply potential line V-VDD which supplies a power supply potential to the peripheral circuit 310 becomes equal to the potential of the power supply potential line V-VSS. When the power switch SW3 is turned off, the potential of the power supply potential line V-VDH which supplies a power supply potential to the backup/recovery driver circuit 320 becomes equal to the potential of the power supply potential line V-VSS. The power switches SW1 to SW3 may be turned on or off at different timings.

### <Application Example of Cache>

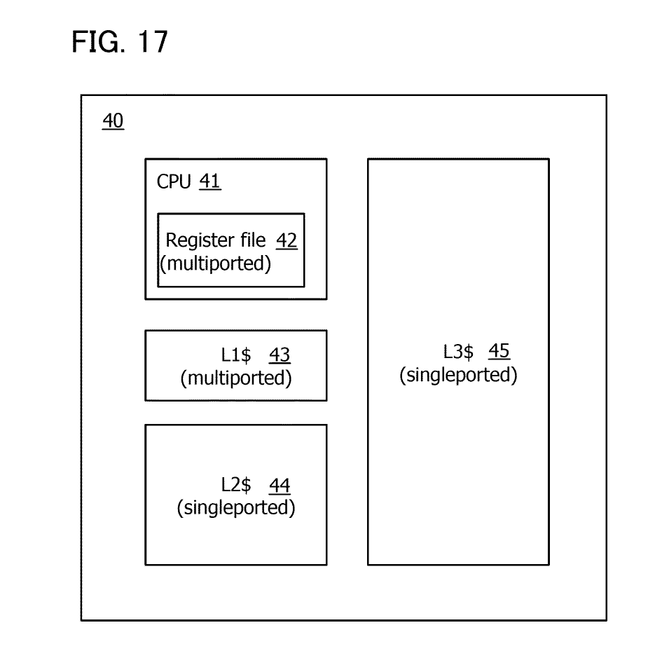

Next, a specific example of the cache 300 illustrated in FIG. 16 is described. A processor 40 illustrated in FIG. 17 includes a CPU 41, a L1 cache 43, a L2 cache 44, and a L3 cache 45. The CPU 41 includes a register file 42.

The cache 300 illustrated in FIG. 16 can be applied to an L1 cache 43 (L1$ in the figure), an L2 cache 44 (L2$ in the figure), and an L3 cache 45 (L3$ in the figure). The cache 300 can also be applied to the register file 42 in the CPU 41.

To each of the L2 cache 44 and the L3 cache 45, a cache including the memory cell MC including the single-port SRAM 101 is preferably applied. To each of the register file 42 and the L1 cache 43, a cache including the memory cell MC including the multiport SRAM 101 capable of reading and writing data at the same time is preferably applied. Since the multiport SRAM is capable of reading and writing data at the same time, reading and writing to different addresses can be performed at the same time.

As illustrated in FIG. 17, the caches each including the multiport SRAM are provided near the CPU 41 and the caches each including the single-port SRAM are provided far from the CPU 41. This configuration can achieve lower power consumption and higher-speed operation of the processor 40.

### Embodiment 4

In this embodiment, the OS transistor with a low off-state current which is described in the above embodiment and the oxide semiconductor included in the semiconductor layer of the OS transistor are described.

The OS transistor mentioned in the above embodiment as a transistor with a low off-state current can achieve a lower off-state current than a Si transistor.

The off-state current of an OS transistor can be reduced by reducing the concentration of impurities in an oxide semiconductor to make the oxide semiconductor intrinsic or substantially intrinsic. The term “substantially intrinsic” refers to the state where an oxide semiconductor has a carrier density lower than 1×10¹⁷/cm³, preferably lower than 1×10¹⁵/cm³, further preferably lower than 1×10¹³/cm³. In the oxide semiconductor, hydrogen, nitrogen, carbon, silicon, and metal elements that are not main components are impurities. For example, hydrogen and nitrogen form donor levels to increase the carrier density.

A transistor including an intrinsic or substantially intrinsic oxide semiconductor has a low carrier density and thus is less likely to have a negative threshold voltage. In addition, because of few carrier traps in the oxide semiconductor, the transistor including the oxide semiconductor has small variation in electrical characteristics and high reliability. Furthermore, the transistor including the oxide semiconductor can make the off-state current extremely low.

The OS transistor with reduced off-state current can exhibit a normalized off-state current per micrometer of a channel width of 1×10⁻¹⁸ A or less, preferably 1×10⁻²¹ A or less, more preferably 1×10⁻²⁴ A or less at room temperature (approximately 25° C.), or 1×10⁻¹⁵ A or less, preferably 1×10⁻¹⁸ A or less, more preferably 1×10⁻²¹ A or less at 85° C.

Note that the off-state current of an n-channel transistor refers to a current that flows between a source and a drain when the transistor is off. For example, the off-state current of an n-channel transistor with a threshold voltage of approximately 0 V to 2 V refers to a current that flows between a source and a drain when a negative voltage is applied between a gate and the source.

Thus, in the memory cell MC, charge can be held when the OS transistor is turned off.

An OS transistor used as a component of the memory cell MC can have favorable switching characteristics in addition to low off-state current.

An OS transistor used for the memory cell MC is formed over an insulating surface. Therefore, unlike in a Si transistor using a semiconductor substrate as it is as a channel formation region, parasitic capacitance is not formed between a gate electrode and a body or a semiconductor substrate. Consequently, with the use of the OS transistor, carriers can be controlled easily with a gate electric field, and favorable switching characteristics can be obtained.

### <Oxide Semiconductor>

Next, an oxide semiconductor layer that can be used as a semiconductor layer of the OS transistor is described.

An oxide semiconductor used for a channel formation region in the semiconductor layer of the transistor preferably contains at least indium (In) or zinc (Zn). In particular, In and Zn are preferably contained. A stabilizer for strongly bonding oxygen is preferably contained in addition to In and Zn. As a stabilizer, at least one of gallium (Ga), tin (Sn), zirconium (Zr), hafnium (Hf), and aluminum (Al) may be contained.

As another stabilizer, one or more kinds of lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu) may be contained.

As the oxide semiconductor used for the semiconductor layer of the transistor, for example, any of the following can be used: indium oxide, tin oxide, zinc oxide, an In—Zn-based oxide, a Sn—Zn-based oxide, an Al—Zn-based oxide, a Zn—Mg-based oxide, a Sn—Mg-based oxide, an In—Mg-based oxide, an In—Ga-based oxide, an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—Zr—Zn-based oxide, an In—Ti—Zn-based oxide, an In—Sc—Zn-based oxide, an In—Y—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, an In—Lu—Zn-based oxide, an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and an In—Hf—Al—Zn-based oxide.

For example, an In—Ga—Zn-based oxide with an atomic ratio of In:Ga:Zn=1:1:1, 3:1:2, or 2:1:3, or an oxide with an atomic ratio close to the above atomic ratios can be used.

When the oxide semiconductor film forming the semiconductor layer contains a large amount of hydrogen, the hydrogen and the oxide semiconductor are bonded to each other, so that part of the hydrogen serves as a donor and causes generation of an electron that is a carrier. As a result, the threshold voltage of the transistor shifts in the negative direction. Therefore, it is preferable that, after formation of the oxide semiconductor film, dehydration treatment (dehydrogenation treatment) be performed to remove hydrogen or moisture from the oxide semiconductor film so that the oxide semiconductor film is highly purified to contain impurities as little as possible.

Note that oxygen in the oxide semiconductor film is also reduced by the dehydration treatment (dehydrogenation treatment) in some cases. Therefore, it is preferable that oxygen be added to the oxide semiconductor film to fill oxygen vacancies increased by the dehydration treatment (dehydrogenation treatment) of the oxide semiconductor film. In this specification and the like, supplying oxygen to an oxide semiconductor film may be expressed as oxygen adding treatment, and treatment for making the oxygen content of an oxide semiconductor film be in excess of that in the stoichiometric composition may be expressed as treatment for making an oxygen-excess state.

In this manner, hydrogen or moisture is removed from the oxide semiconductor film by the dehydration treatment (dehydrogenation treatment) and oxygen vacancies therein are filled by the oxygen adding treatment, whereby the oxide semiconductor film can be turned into an i-type (intrinsic) oxide semiconductor film or a substantially i-type (intrinsic) oxide semiconductor film which is extremely close to an i-type oxide semiconductor film. Note that “substantially intrinsic” means that the oxide semiconductor film contains extremely few (close to zero) carriers derived from a donor and has a carrier density of 1×10¹⁷/cm³ or lower, 1×10¹⁶/cm³ or lower, 1×10¹⁵/cm³ or lower, 1×10¹⁴/cm³ or lower, or 1×10¹³/cm³ or lower.

In this manner, the transistor including an i-type (intrinsic) or substantially i-type oxide semiconductor film can have extremely favorable off-state current characteristics.

A structure of the oxide semiconductor film is described below.

An oxide semiconductor film is classified roughly into a non-single-crystal oxide semiconductor film and a single-crystal oxide semiconductor film. The non-single-crystal oxide semiconductor film includes any of a c-axis aligned crystalline oxide semiconductor (CAAC-OS) film, a polycrystalline oxide semiconductor film, a microcrystalline oxide semiconductor film, an amorphous oxide semiconductor film, and the like.

First, a CAAC-OS film is described.

The CAAC-OS film is an oxide semiconductor film including a plurality of c-axis aligned crystal parts.

With a transmission electron microscope (TEM), a combined analysis image (also referred to as a high-resolution TEM image) of a bright-field image and a diffraction pattern of the CAAC-OS film is observed. Consequently, a plurality of crystal parts can be observed clearly. However, in the high-resolution TEM image, a boundary between crystal parts, i.e., a grain boundary is not observed clearly. Thus, in the CAAC-OS film, a reduction in electron mobility due to the grain boundary is less likely to occur.

According to the high-resolution cross-sectional TEM image of the CAAC-OS film observed in a direction substantially parallel to a sample surface, metal atoms are arranged in a layered manner in the crystal parts. Each metal atom layer has a shape reflecting a surface over which the CAAC-OS film is formed (hereinafter, a surface over which the CAAC-OS film is formed is referred to as a formation surface) or a top surface of the CAAC-OS film, and is arranged parallel to the formation surface or the top surface of the CAAC-OS film.

According to the high-resolution plan-view TEM image of the CAAC-OS film observed in a direction substantially perpendicular to the sample surface, metal atoms are arranged in a triangular or hexagonal configuration in the crystal parts. However, there is no regularity of arrangement of metal atoms between different crystal parts.

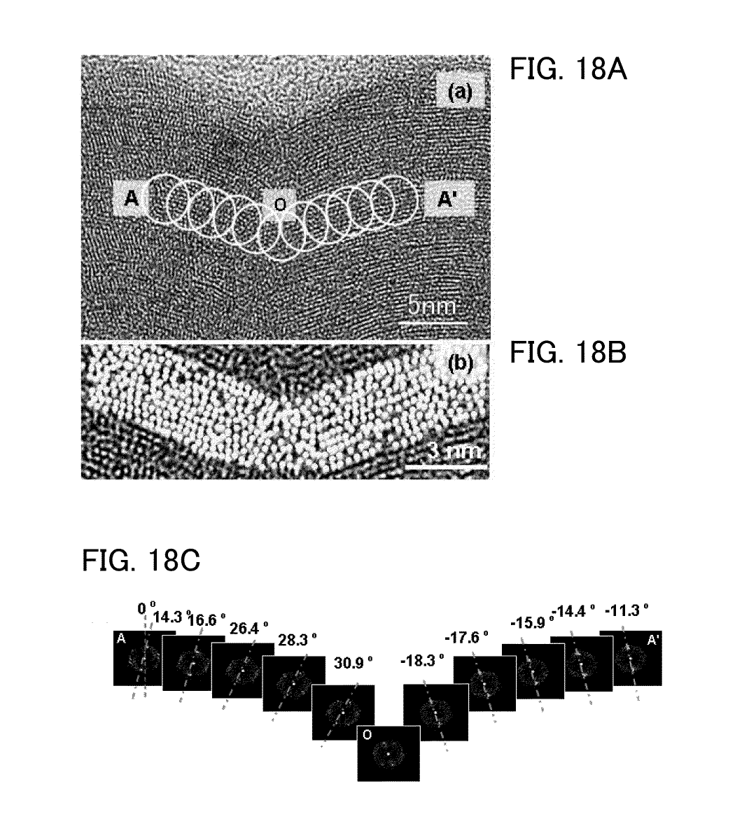

FIG. 18A is a high-resolution cross-sectional TEM image of the CAAC-OS film. FIG. 18B is a high-resolution cross-sectional TEM image obtained by enlarging the image of FIG. 18A. In FIG. 18B, atomic arrangement is highlighted for easy understanding.

FIG. 18C is Fourier transform images of regions each surrounded by a circle (the diameter is approximately 4 nm) between A and O and between O and A′ in FIG. 18A. C-axis alignment can be observed in each region in FIG. 18C. The c-axis direction between A and O is different from that between O and A′, which indicates that a grain in the region between A and O is different from that between O and A′. In addition, between A and O, the angle of the c-axis continuously and gradually changes from 14.3°, 16.6°, to 26.4°. Similarly, the angle of the c-axis between O and A′ continuously changes from −18.3°, −17.6°, to −15.9°.

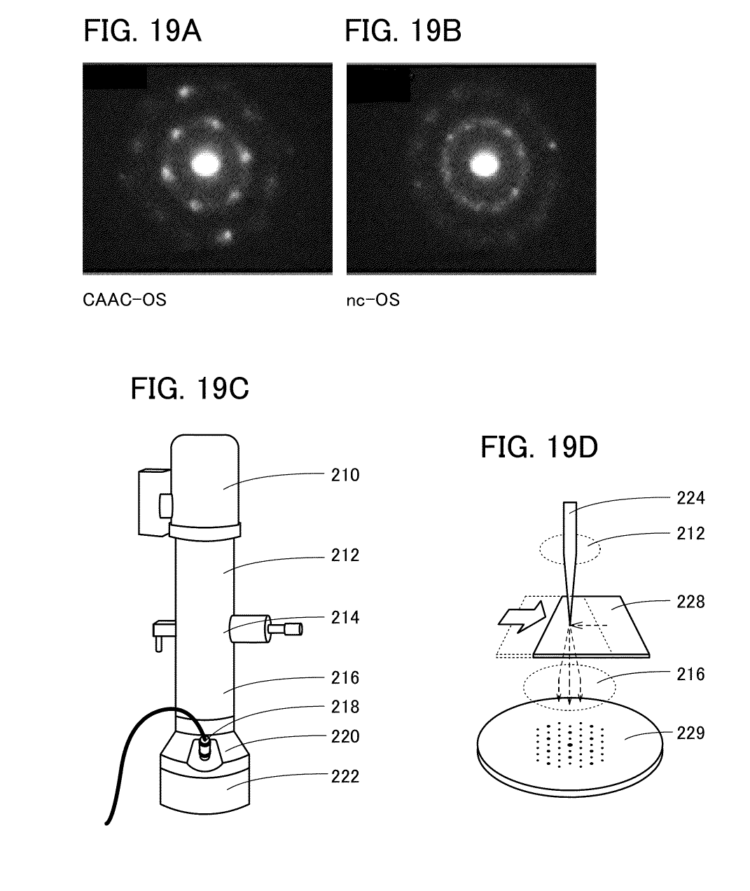

Note that in an electron diffraction pattern of the CAAC-OS film, spots (bright spots) having alignment are shown. For example, when electron diffraction with an electron beam having a diameter greater than or equal to 1 nm and less than or equal to 30 nm (such electron diffraction is also referred to as nanobeam electron diffraction) is performed on the top surface of the CAAC-OS film, spots are observed (see FIG. 19A).

From the results of the high-resolution cross-sectional TEM image and the high-resolution plan-view TEM image, alignment is found in the crystal parts in the CAAC-OS film.

Most of the crystal parts included in the CAAC-OS film each fit inside a cube whose one side is less than 100 nm. Thus, there is a case where a crystal part included in the CAAC-OS film fits inside a cube whose one side is less than 10 nm, less than 5 nm, or less than 3 nm. Note that when a plurality of crystal parts included in the CAAC-OS film are connected to each other, one large crystal region is formed in some cases. For example, a crystal region with an area of 2500 nm² or more, 5 μm² or more, or 1000 μm² or more is observed in some cases in the high-resolution plan-view TEM image.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor film of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axes and b-axes are irregularly oriented between crystal parts, the c-axes are aligned in a direction parallel to a normal vector of a formation surface or a normal vector of a top surface. Thus, each metal atom layer arranged in a layered manner observed in the high-resolution cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned in a direction parallel to a normal vector of a formation surface or a normal vector of a top surface of the CAAC-OS film. Thus, for example, in the case where the shape of the CAAC-OS film is changed by etching or the like, the c-axis might not be necessarily parallel to a normal vector of a formation surface or a normal vector of a top surface of the CAAC-OS film.

Distribution of c-axis aligned crystal parts in the CAAC-OS film is not necessarily uniform. For example, in the case where crystal growth leading to the crystal parts of the CAAC-OS film occurs from the vicinity of the top surface of the CAAC-OS film, the proportion of the c-axis aligned crystal parts in the vicinity of the top surface is higher than that in the vicinity of the formation surface in some cases. When an impurity is added to the CAAC-OS film, a region to which the impurity is added is altered, and the proportion of the c-axis aligned crystal parts in the CAAC-OS film varies depending on regions, in some cases.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ not appear at around 36°.

The CAAC-OS film is an oxide semiconductor film having low impurity concentration. The impurity is an element other than the main components of the oxide semiconductor film, such as hydrogen, carbon, silicon, or a transition metal element. In particular, an element that has higher bonding strength to oxygen than a metal element included in the oxide semiconductor film, such as silicon, disturbs the atomic arrangement of the oxide semiconductor film by depriving the oxide semiconductor film of oxygen and causes a decrease in crystallinity. Furthermore, a heavy metal such as iron or nickel, argon, carbon dioxide, or the like has a large atomic radius (molecular radius), and thus disturbs the atomic order of the oxide semiconductor film and causes a decrease in crystallinity when it is contained in the oxide semiconductor film. Note that the impurity contained in the oxide semiconductor film might serve as a carrier trap or a carrier generation source.

The CAAC-OS film is an oxide semiconductor film having a low density of defect states. In some cases, oxygen vacancies in the oxide semiconductor film serve as carrier traps or serve as carrier generation sources when hydrogen is captured therein.

The state in which impurity concentration is low and density of defect states is low (the number of oxygen vacancies is small) is referred to as a “highly purified intrinsic” or “substantially highly purified intrinsic” state. A highly purified intrinsic or substantially highly purified intrinsic oxide semiconductor film has few carrier generation sources, and thus can have a low carrier density. Thus, a transistor including the oxide semiconductor film rarely has a negative threshold voltage (is rarely normally on). The highly purified intrinsic or substantially highly purified intrinsic oxide semiconductor film has few carrier traps. Accordingly, the transistor including the oxide semiconductor film has little variation in electrical characteristics and high reliability. Charge trapped by the carrier traps in the oxide semiconductor film takes a long time to be released, and might behave like fixed charge. Thus, the transistor that includes the oxide semiconductor film having high impurity concentration and a high density of defect states has unstable electrical characteristics in some cases.

In a transistor including the CAAC-OS film, changes in electrical characteristics of the transistor due to irradiation with visible light or ultraviolet light are small.

Next, a polycrystalline oxide semiconductor film is described.

In a high-resolution TEM image of the polycrystalline oxide semiconductor film, crystal grains are observed. In most cases, the crystal grain size in the polycrystalline oxide semiconductor film is greater than or equal to 2 nm and less than or equal to 300 nm, greater than or equal to 3 nm and less than or equal to 100 nm, or greater than or equal to 5 nm and less than or equal to 50 nm in the high-resolution TEM image, for example. Moreover, in the high-resolution TEM image of the polycrystalline oxide semiconductor film, a grain boundary may be observed.

The polycrystalline oxide semiconductor film may include a plurality of crystal grains, and alignment of crystals may be different in the plurality of crystal grains. A polycrystalline oxide semiconductor film is subjected to structural analysis with an XRD apparatus. For example, when the polycrystalline oxide semiconductor film including an InGaZnO₄ crystal is analyzed by an out-of-plane method, peaks of 2θ appear at around 31°, 36°, and the like in some cases.

The polycrystalline oxide semiconductor film has high crystallinity and thus has high electron mobility in some cases. Accordingly, a transistor including the polycrystalline oxide semiconductor film has high field-effect mobility. Note that there are cases in which an impurity is segregated at the grain boundary in the polycrystalline oxide semiconductor film. Moreover, the grain boundary of the polycrystalline oxide semiconductor film becomes a defect state. Since the grain boundary of the polycrystalline oxide semiconductor film may serve as a carrier trap or a carrier generation source, a transistor including the polycrystalline oxide semiconductor film has larger variation in electrical characteristics and lower reliability than a transistor including a CAAC-OS film in some cases.

Next, a microcrystalline oxide semiconductor film is described.

A microcrystalline oxide semiconductor film has a region in which a crystal part is observed and a region in which a crystal part is not observed clearly in a high-resolution TEM image. In most cases, a crystal part in the microcrystalline oxide semiconductor film is greater than or equal to 1 nm and less than or equal to 100 nm, or greater than or equal to 1 nm and less than or equal to 10 nm. A microcrystal with a size greater than or equal to 1 nm and less than or equal to 10 nm, or a size greater than or equal to 1 nm and less than or equal to 3 nm is specifically referred to as nanocrystal (nc). An oxide semiconductor film including nanocrystal is referred to as a nanocrystalline oxide semiconductor (nc-OS) film. In a high resolution TEM image of the nc-OS film, a grain boundary cannot be found clearly in the nc-OS film in some cases.

In the nc-OS film, a microscopic region (for example, a region with a size greater than or equal to 1 nm and less than or equal to 10 nm, in particular, a region with a size greater than or equal to 1 nm and less than or equal to 3 nm) has a periodic atomic order. Note that there is no regularity of crystal orientation between different crystal parts in the nc-OS film. Thus, the orientation of the whole film is not observed. Accordingly, in some cases, the nc-OS film cannot be distinguished from an amorphous oxide semiconductor film depending on an analysis method. For example, when the nc-OS film is subjected to structural analysis by an out-of-plane method with an XRD apparatus using an X-ray having a diameter larger than that of a crystal part, a peak which shows a crystal plane does not appear. Furthermore, a halo pattern is shown in an electron diffraction pattern (also referred to as a selected-area electron diffraction pattern) of the nc-OS film obtained by using an electron beam having a probe diameter larger than the diameter of a crystal part (e.g., larger than or equal to 50 nm). Meanwhile, spots are shown in a nanobeam electron diffraction pattern of the nc-OS film obtained by using an electron beam having a probe diameter close to, or smaller than the diameter of a crystal part. Furthermore, in a nanobeam electron diffraction pattern of the nc-OS film, regions with high luminance in a circular (ring) pattern are shown in some cases. Also in a nanobeam electron diffraction pattern of the nc-OS film, a plurality of spots are shown in a ring-like region in some cases (see FIG. 19B).

The nc-OS film is an oxide semiconductor film that has high regularity as compared to an amorphous oxide semiconductor film. Therefore, the nc-OS film has a lower density of defect states than an amorphous oxide semiconductor film. Note that there is no regularity of crystal orientation between different crystal parts in the nc-OS film. Therefore, the nc-OS film has a higher density of defect states than the CAAC-OS film.

Thus, the nc-OS film may have a higher carrier density than the CAAC-OS film. The oxide semiconductor film having a high carrier density may have high electron mobility. Thus, a transistor including the nc-OS film may have high field-effect mobility. The nc-OS film has a higher density of defect states than the CAAC-OS film, and thus may have a large number of carrier traps. Consequently, a transistor including the nc-OS film has larger variation in electrical characteristics and lower reliability than a transistor including the CAAC-OS film. The nc-OS film can be formed easily as compared to the CAAC-OS film because the nc-OS film can be formed even when a relatively large amount of impurities are included; thus, depending on the purpose, the nc-OS film can be favorably used in some cases. Therefore, a memory device including the transistor including the nc-OS film can be manufactured with high productivity in some cases.

Next, an amorphous oxide semiconductor film is described.

The amorphous oxide semiconductor film has disordered atomic arrangement and no crystal part. For example, the amorphous oxide semiconductor film does not have a specific state as in quartz.

In a high-resolution TEM image of the amorphous oxide semiconductor film, crystal parts cannot be found.

When the amorphous oxide semiconductor film is subjected to structural analysis by an out-of-plane method with an XRD apparatus, a peak which shows a crystal plane does not appear. A halo pattern is shown in an electron diffraction pattern of the amorphous oxide semiconductor film. Furthermore, a halo pattern is shown but a spot is not shown in a nanobeam electron diffraction pattern of the amorphous oxide semiconductor film.

The amorphous oxide semiconductor film contains impurities such as hydrogen at a high concentration. In addition, the amorphous oxide semiconductor film has a high density of defect states.

The oxide semiconductor film having a high impurity concentration and a high density of defect states has many carrier traps or many carrier generation sources.

Accordingly, the amorphous oxide semiconductor film has a much higher carrier density than the nc-OS film. Therefore, a transistor including the amorphous oxide semiconductor film tends to be normally on. Thus, in some cases, such an amorphous oxide semiconductor layer can be preferably applied to a transistor which needs to be normally on. Since the amorphous oxide semiconductor film has a high density of defect states, carrier traps might be increased. Consequently, a transistor including the amorphous oxide semiconductor film has larger variation in electrical characteristics and lower reliability than a transistor including the CAAC-OS film or the nc-OS film.

Next, a single-crystal oxide semiconductor film is described.

The single-crystal oxide semiconductor film has a lower impurity concentration and a lower density of defect states (few oxygen vacancies). Thus, the carrier density can be decreased. Accordingly, a transistor including the single-crystal oxide semiconductor film is unlikely to be normally on. Moreover, since the single-crystal oxide semiconductor film has a lower impurity concentration and a lower density of defect states, carrier traps might be reduced. Thus, the transistor including the single-crystal oxide semiconductor film has small variation in electrical characteristics and accordingly has high reliability.

Note that when the oxide semiconductor film has few defects, the density thereof is increased. When the oxide semiconductor film has high crystallinity, the density thereof is increased. When the oxide semiconductor film has a lower concentration of impurities such as hydrogen, the density thereof is increased. The single-crystal oxide semiconductor film has a higher density than the CAAC-OS film. The CAAC-OS film has a higher density than the microcrystalline oxide semiconductor film. The polycrystalline oxide semiconductor film has a higher density than the microcrystalline oxide semiconductor film. The microcrystalline oxide semiconductor film has a higher density than the amorphous oxide semiconductor film.

Note that an oxide semiconductor film may have a structure having physical properties between the nc-OS film and the amorphous oxide semiconductor film. The oxide semiconductor film having such a structure is specifically referred to as an amorphous-like oxide semiconductor (amorphous-like OS) film.

In a high-resolution TEM image of the amorphous-like OS film, a void can be observed. Furthermore, in the high-resolution TEM image, there are a region where a crystal part is clearly observed and a region where a crystal part is not observed. In the amorphous-like OS film, crystallization by a slight amount of electron beam used for TEM observation occurs and growth of the crystal part is found sometimes. In contrast, crystallization by a slight amount of electron beam used for TEM observation is scarcely observed in the nc-OS film having good quality.

Note that the crystal part size in the amorphous-like OS film and the nc-OS film can be measured using high-resolution TEM images. For example, an InGaZnO₄ crystal has a layered structure in which two Ga—Zn—O layers are included between In—O layers. A unit cell of the InGaZnO₄ crystal has a structure in which nine layers of three In—O layers and six Ga—Zn—O layers are layered in the c-axis direction. Accordingly, the spacing between these adjacent layers is equivalent to the lattice spacing on the (009) plane (also referred to as d value). The value is calculated to 0.29 nm from crystal structure analysis. Thus, each of the lattice fringes in which the spacing therebetween is from 0.28 nm to 0.30 nm is regarded to correspond to the a-b plane of the InGaZnO₄ crystal, focusing on the lattice fringes in the high-resolution TEM image. The maximum length of the region in which the lattice fringes are observed is regarded as the size of the crystal parts of the amorphous-like OS film and the nc-OS film. Note that the crystal part whose size is 0.8 nm or larger is selectively evaluated.

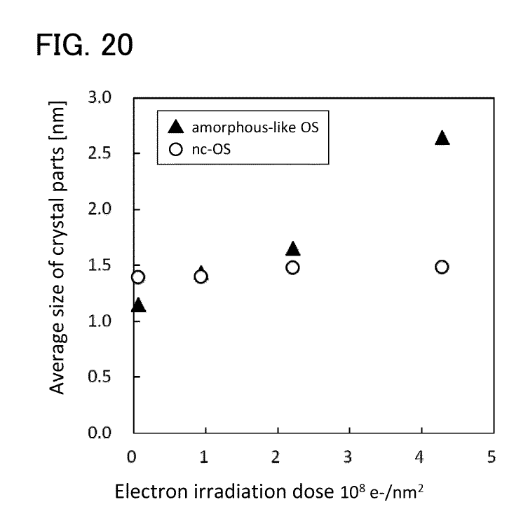

FIG. 20 shows the change in the average size of crystal parts (at 20 points to 40 points) in the amorphous-like OS film and the nc-OS film using the high-resolution TEM images. From FIG. 20, it is found that the crystal part size in the amorphous-like OS film increases with an increase in the cumulative electron dose. Specifically, the crystal part of approximately 1.2 nm at the start of TEM observation grows to a size of approximately 2.6 nm at a cumulative electron dose of 4.2×10⁸ e⁻/nm². In contrast, the crystal part size in the good-quality nc-OS film shows little change from the start of electron irradiation to a cumulative electron dose of 4.2×10⁸ e⁻/nm² regardless of the cumulative electron dose.

Furthermore, in FIG. 20, by linear approximation of the change in the crystal part size in the amorphous-like OS film and the nc-OS film and extrapolation to a cumulative electron dose of 0 e⁻/nm², the average size of the crystal part is found to be a positive value. This means that the crystal parts exist in the amorphous-like OS film and the nc-OS film before TEM observation.

Note that an oxide semiconductor film may be a stacked film including two or more films of an amorphous oxide semiconductor film, a microcrystalline oxide semiconductor film, and a CAAC-OS film, for example.

In the case where the oxide semiconductor film has a plurality of structures, the structures can be analyzed using nanobeam electron diffraction in some cases.

FIG. 19C illustrates a transmission electron diffraction measurement apparatus. The transmission electron diffraction measurement apparatus includes an electron gun chamber 210, an optical system 212 below the electron gun chamber 210, a sample chamber 214 below the optical system 212, an optical system 216 below the sample chamber 214, an observation chamber 220 below the optical system 216, a camera 218 provided for the observation chamber 220, and a film chamber 222 below the observation chamber 220. The camera 218 is provided to face toward the inside of the observation chamber 220. Note that the film chamber 222 is not necessarily provided.

FIG. 19D illustrates the internal structure of the transmission electron diffraction measurement apparatus in FIG. 19C. In the transmission electron diffraction measurement apparatus, a substance 228 which is positioned in the sample chamber 214 is irradiated with electrons emitted from an electron gun installed in the electron gun chamber 210 through the optical system 212. The electrons which have passed through the substance 228 enter a fluorescent plate 229 which is installed in the observation chamber 220 through the optical system 216. On the fluorescent plate 229, a pattern corresponding to the intensity of the incident electrons appears, which enables measurement of a transmission electron diffraction pattern.

The camera 218 is installed so as to face the fluorescent plate 229 and can take a picture of a pattern appearing in the fluorescent plate 229. An angle formed by a straight line which passes through the center of a lens of the camera 218 and the center of the fluorescent plate 229 and an upper surface of the fluorescent plate 229 is, for example, greater than or equal to 15° and less than or equal to 80°, greater than or equal to 30° and less than or equal to 75°, or greater than or equal to 45° and less than or equal to 70°. As the angle is reduced, distortion of the transmission electron diffraction pattern taken by the camera 218 becomes larger. Note that if the angle is obtained in advance, the distortion of an obtained transmission electron diffraction pattern can be corrected. Note that the film chamber 222 may be provided with the camera 218. For example, the camera 218 may be set in the film chamber 222 so as to be opposite to the incident direction of electrons 224. In this case, a transmission electron diffraction pattern with less distortion can be taken from the rear surface of the fluorescent plate 229.

A holder for fixing the substance 228 that is a sample is provided in the sample chamber 214. The holder transmits electrons passing through the substance 228. The holder may have, for example, a function of moving the substance 228 in the direction of the X, Y, and Z axes. The movement function of the holder may have an accuracy of moving the substance in the range of, for example, 1 nm to 10 nm, 5 nm to 50 nm, 10 nm to 100 nm, 50 nm to 500 nm, and 100 nm to 1 μm. The range is preferably determined to be an optimal range for the structure of the substance 228.

Then, a method of measuring a transmission electron diffraction pattern of a substance by the transmission electron diffraction measurement apparatus described above is described.

For example, changes in the structure of a substance can be observed by changing (or by scanning) the irradiation position of the electrons 224 which are a nanobeam on the substance as illustrated in FIG. 19D. At this time, when the substance 228 is a CAAC-OS film, a diffraction pattern shown in FIG. 19A is observed. When the substance 228 is an nc-OS film, a diffraction pattern shown in FIG. 19B is observed.

Even when the substance 228 is a CAAC-OS film, a diffraction pattern similar to that of an nc-OS film or the like is partly observed in some cases. Therefore, the quality of the CAAC-OS film can be evaluated by the proportion of a region where a diffraction pattern of a CAAC-OS film is observed in a predetermined area (also referred to as proportion of CAAC). In the case of a high quality CAAC-OS film, for example, the proportion of CAAC is higher than or equal to 50%, preferably higher than or equal to 80%, further preferably higher than or equal to 90%, still further preferably higher than or equal to 95%. Note that the proportion of a region where a diffraction pattern different from that of a CAAC-OS film is observed is referred to as the proportion of non-CAAC.

For example, transmission electron diffraction patterns were obtained by scanning a top surface of a sample including a CAAC-OS film obtained just after deposition (represented as “as-sputtered”) and a top surface of a sample including a CAAC-OS film subjected to heat treatment at 450° C. in an atmosphere containing oxygen. Here, the proportion of CAAC was obtained in such a manner that diffraction patterns were observed by scanning for 60 seconds at a rate of 5 nm/second and the obtained diffraction patterns were converted into still images every 0.5 seconds. Note that as an electron beam, a nanobeam with a probe diameter of 1 nm was used. The above measurement was performed on six samples. The proportion of CAAC was calculated using the average value of the six samples.

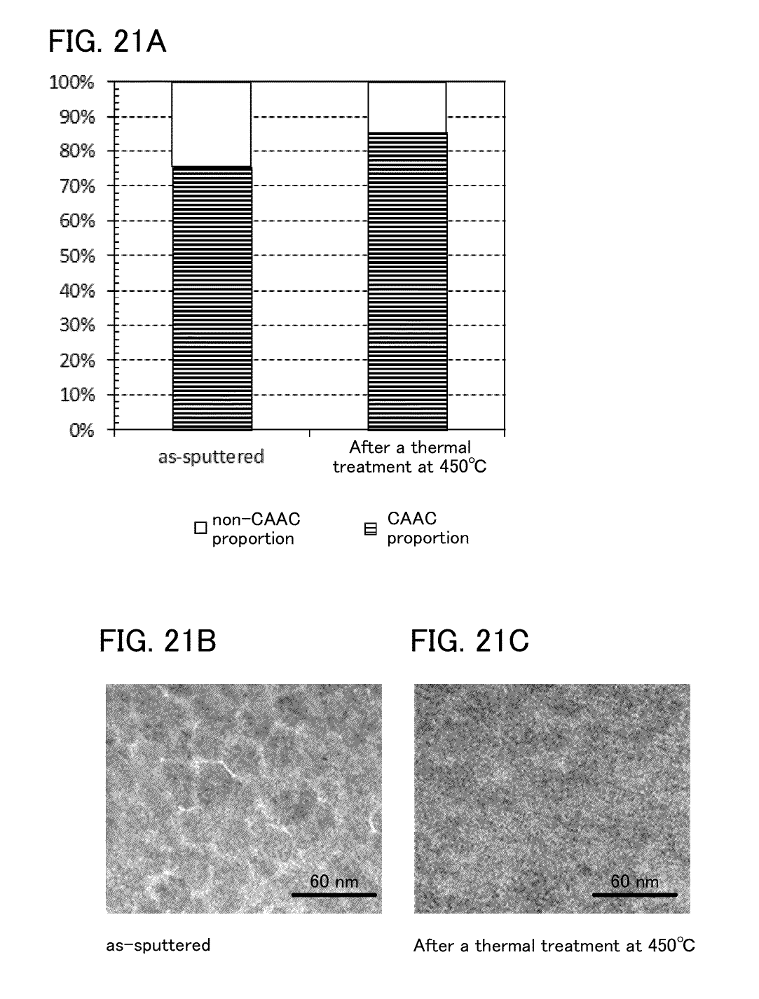

FIG. 21A shows the proportion of CAAC in each sample. The proportion of CAAC of the CAAC-OS film obtained just after the deposition was 75.7% (the proportion of non-CAAC was 24.3%). The proportion of CAAC of the CAAC-OS film subjected to the heat treatment at 450° C. was 85.3% (the proportion of non-CAAC was 14.7%). These results show that the proportion of CAAC obtained after the heat treatment at 450° C. is higher than that obtained just after the deposition. That is, heat treatment at a high temperature (e.g., higher than or equal to 400° C.) reduces the proportion of non-CAAC (increases the proportion of CAAC). Furthermore, the above results also indicate that even when the temperature of the heat treatment is lower than 500° C., the CAAC-OS film can have a high proportion of CAAC.

Here, most of diffraction patterns different from that of a CAAC-OS film are diffraction patterns similar to that of an nc-OS film. Furthermore, an amorphous oxide semiconductor film was not able to be observed in the measurement region. Therefore, the above results suggest that the region having a structure similar to that of an nc-OS film is rearranged by the heat treatment owing to the influence of the structure of the adjacent region, whereby the region becomes CAAC.

FIGS. 21B and 21C are high-resolution plan-view TEM images of the CAAC-OS film obtained just after the deposition and the CAAC-OS film subjected to the heat treatment at 450° C., respectively. Comparison between FIGS. 21B and 21C shows that the CAAC-OS film subjected to the heat treatment at 450° C. has more uniform film quality. That is, the heat treatment at a high temperature improves the film quality of the CAAC-OS film.

With such a measurement method, the structure of an oxide semiconductor film having a plurality of structures can be analyzed in some cases.

Note that the structures, methods, and the like described in this embodiment can be used as appropriate in combination with any of the structures, methods, and the like described in the other embodiments.

### Embodiment 5

Although the conductive layer and the semiconductor layer described in the above embodiments can be formed by a sputtering method, they may be formed by another method, for example, a thermal CVD method. A metal organic chemical vapor deposition (MOCVD) method or an atomic layer deposition (ALD) method may be employed as an example of a thermal CVD method.

A thermal CVD method has an advantage that no defect due to plasma damage is generated since it does not utilize plasma for forming a film.

Deposition by a thermal CVD method may be performed in such a manner that the pressure in a chamber is set to an atmospheric pressure or a reduced pressure, and a source gas and an oxidizer are supplied to the chamber at a time and react with each other in the vicinity of the substrate or over the substrate.

Deposition by an ALD method may be performed in such a manner that the pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves). For example, a first source gas is introduced, an inert gas (e.g., argon or nitrogen) or the like is introduced at the same time as or after the introduction of the first source gas so that the source gases are not mixed, and then a second source gas is introduced. Note that in the case where the first source gas and the inert gas are introduced at a time, the inert gas serves as a carrier gas, and the inert gas may also be introduced at the same time as the introduction of the second source gas. Alternatively, the first source gas may be exhausted by vacuum evacuation instead of the introduction of the inert gas, and then the second source gas may be introduced. The first source gas is adsorbed on the surface of the substrate to form a first single-atomic layer; then the second source gas is introduced to react with the first single-atomic layer; as a result, a second single-atomic layer is stacked over the first single-atomic layer, so that a thin film is formed. The sequence of the gas introduction is repeated more than once until a desired thickness is obtained, whereby a thin film with excellent step coverage can be formed. The thickness of the thin film can be adjusted by the number of repetition times of the sequence of the gas introduction; therefore, an ALD method makes it possible to accurately adjust a thickness and thus is suitable for manufacturing a minute FET.

The conductive layer and the semiconductor layer that are described in the above embodiments can be formed by a thermal CVD method such as an MOCVD method or an ALD method. For example, in the case where an InGaZnO_{X} (X>0) film is formed, trimethylindium, trimethylgallium, and dimethylzinc are used. Note that the chemical formula of trimethylindium is (CH₃)₃In. The chemical formula of trimethylgallium is (CH₃)₃Ga. The chemical formula of dimethylzinc is (CH₃)₂Zn. Without limitation to the above combination, triethylgallium (chemical formula: (C₂H₅)₃Ga) can be used instead of trimethylgallium and diethylzinc (chemical formula: (C₂H₅)₂Zn) can be used instead of dimethylzinc.

For example, in the case where a tungsten film is formed using a deposition apparatus employing ALD, a WF₆ gas and a B₂H₆ gas are sequentially introduced more than once to form an initial tungsten film, and then a WF₆ gas and an H₂ gas are introduced at a time, so that a tungsten film is formed. Note that an SiH₄ gas may be used instead of a B₂H₆ gas.

For example, in the case where an oxide semiconductor film, e.g., an InGaZnO_{X} (X>0) film is formed using a deposition apparatus employing ALD, an In(CH₃)₃ gas and an O₃ gas are sequentially introduced more than once to form an InO₂ layer, a Ga(CH₃)₃ gas and an O₃ gas are introduced at a time to form a GaO layer, and then a Zn(CH₃)₂ gas and an O₃ gas are introduced at a time to form a ZnO layer. Note that the order of these layers is not limited to this example. A mixed compound layer such as an InGaO₂ layer, an InZnO₂ layer, a GaInO layer, a ZnInO layer, or a GaZnO layer may be formed by mixing of these gases. Note that although an H₂O gas which is obtained by bubbling with an inert gas such as Ar may be used instead of an O₃ gas, it is preferable to use an O₃ gas, which does not contain H. Instead of an In(CH₃)₃ gas, an In(C₂H₅)₃ gas may be used. Alternatively, a Zn(CH₃)₂ gas may be used.

The structure described in this embodiment can be used in appropriate combination with any of the structures described in the other embodiments.

### Embodiment 6

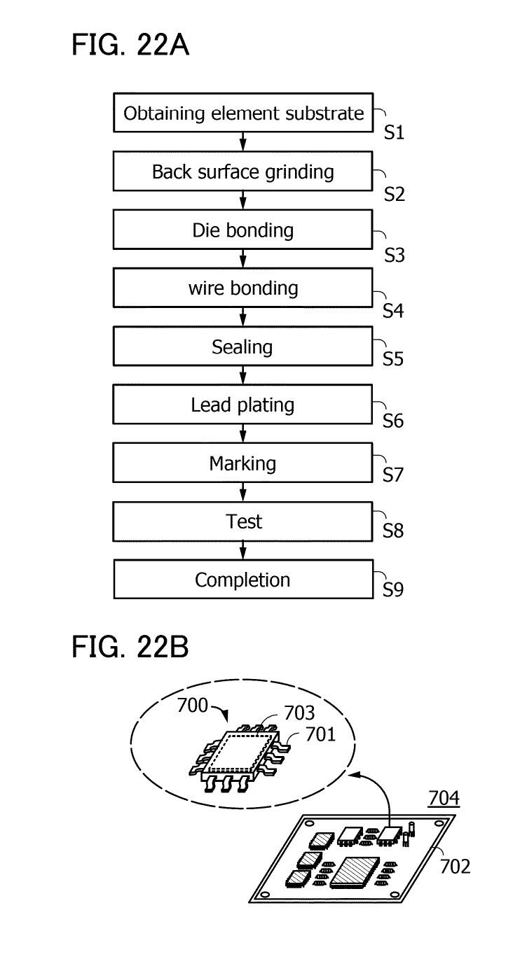

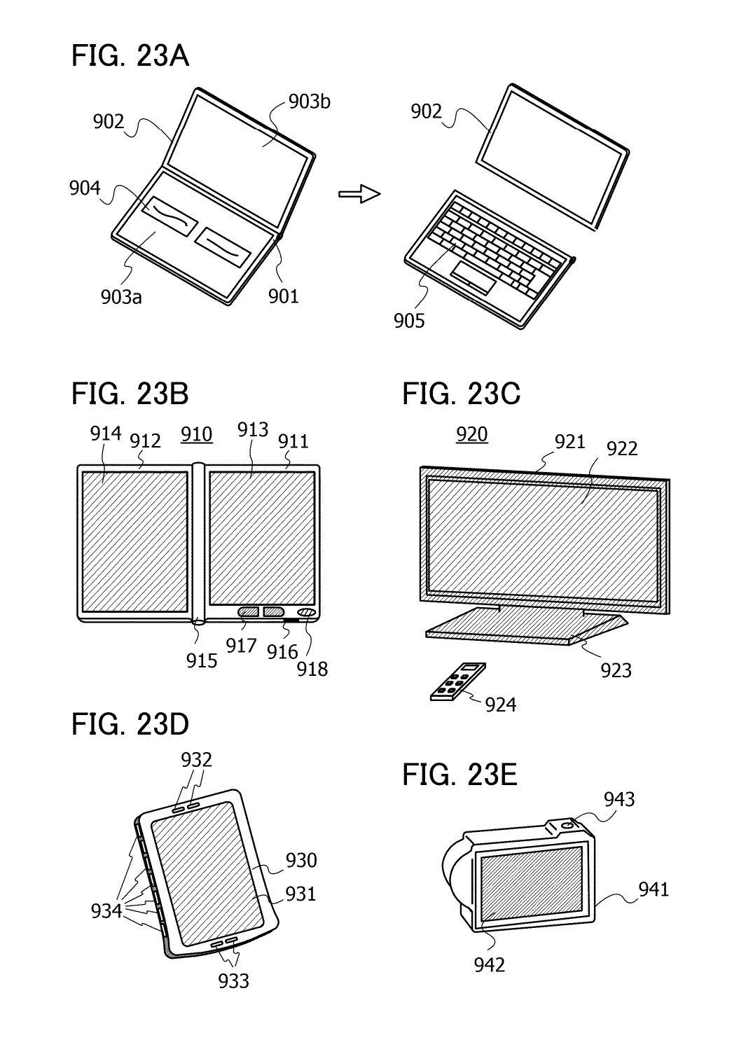

In this embodiment, application examples of the memory device described in the above embodiments to an electronic component and to an electronic device including the electronic component are described with reference to FIGS. 22A and 22B and FIGS. 23A to 23E.

FIG. 22A shows an example in which the memory device described in the above embodiments is used to manufacture an electronic component. Note that the electronic component is also referred to as a semiconductor package or an IC package. This electronic component has a plurality of standards and names depending on a terminal extraction direction and a terminal shape. Thus, examples of the electronic component are described in this embodiment.

A memory device including the transistors illustrated in FIG. 4 and FIG. 5 in Embodiment 1 is completed by integrating detachable components on a printed circuit board through the assembly process (post-process).

The post-process can be completed through steps shown in FIG. 22A.

Specifically, after an element substrate obtained in the preceding process is completed (Step S1), a back surface of the substrate is ground (Step S2). The substrate is thinned in this step to reduce a warp or the like of the substrate in the preceding process and to reduce the size of the component itself.

After the back surface of the substrate is ground, a dicing step is performed to separate the substrate into a plurality of chips. Then, a die bonding step of individually picking up separate chips to be mounted on and bonded to a lead frame is performed (Step S3). To bond a chip and a lead frame in the die bonding step, a method such as resin bonding or tape-automated bonding is selected as appropriate depending on products. Note that in the die bonding step, a chip may be mounted on an interposer to be bonded.

Next, wiring bonding for electrically connecting a lead of the lead frame and an electrode on a chip through a metal wire is performed (Step S4). As a metal wire, a silver wire or a gold wire can be used. For wire bonding, ball bonding or wedge bonding can be employed.

A wire-bonded chip is subjected to a molding step of sealing the chip with an epoxy resin or the like (Step S5). With the molding step, the inside of the electronic component is filled with a resin, thereby reducing damage to the circuit portion and the wire embedded in the component caused by external mechanical force as well as reducing deterioration of characteristics due to moisture or dust.

Subsequently, the lead of the lead frame is plated. Then, the lead is cut and processed into a predetermined shape (Step S6). Through the plating process, corrosion of the lead can be prevented, and soldering for mounting the electronic component on a printed circuit board in a later step can be performed with higher reliability.

Next, printing process (marking) is performed on a surface of the package (Step S7). Then, through a final test step (Step S8), the electronic component is completed (Step S9).

The above electronic component can include the memory device described in the above embodiments. Thus, the electronic component which achieves a smaller size and higher-speed operation can be obtained.

FIG. 22B is a schematic perspective view of the completed electronic component. FIG. 22B is a schematic perspective view illustrating a quad flat package (QFP) as an example of the electronic component. A lead 701 and a circuit portion 703 of an electronic component 700 are illustrated in FIG. 22B. The electronic component 700 in FIG. 22B is, for example, mounted on a printed circuit board 702. When a plurality of electronic components 700 are used in combination and electrically connected to each other over the printed circuit board 702, the electronic components 700 can be mounted on an electronic device. A completed semiconductor device 704 is provided in the electronic device or the like.

Then, applications of the electronic component to an electronic device such as a computer, a portable information terminal (including a mobile phone, a portable game machine, an audio reproducing device, and the like), electronic paper, a television device (also referred to as a television or a television receiver), or a digital video camera are described.

FIG. 23A illustrates a portable information terminal, which includes a housing 901, a housing 902, a first display portion 903a, a second display portion 903b, and the like. The semiconductor device described in the above embodiments is provided in at least one of the housings 901 and 902. Thus, the portable information terminal which achieves a smaller size and higher-speed operation can be obtained.

Note that the first display portion 903a is a panel having a touch input function, and for example, as illustrated in the left of FIG. 23A, the “touch input” and the “keyboard input” can be selected by a selection button 904 displayed on the first display portion 903a. Since the selection buttons with a variety of sizes can be displayed, the portable information terminal can be easily used by people of any generation. In the case where the “keyboard input” is selected, for example, a keyboard 905 is displayed on the first display portion 903a as illustrated in the right of FIG. 23A. With the keyboard 905, letters can be input quickly by keyboard input as in the case of using a conventional information terminal, for example.

Furthermore, one of the first display portion 903a and the second display portion 903b can be detached from the portable information terminal as illustrated in the right of FIG. 23A. Providing the second display portion 903b with a touch input function makes the information terminal convenient to carry because the weight can be further reduced and the information terminal can be operated with one hand while the other hand supports the housing 902.

The portable information terminal in FIG. 23A can have a function of displaying a variety of information (e.g., still images, moving images, and text images), a function of displaying a calendar, a date, the time, or the like on the display portion, a function of operating or editing the information displayed on the display portion, a function of controlling processing by a variety of software (programs), and the like. Furthermore, an external connection terminal (e.g., an earphone terminal or a USB terminal), a recording medium insertion portion, and the like may be provided on the rear surface or the side surface of the housing.

The portable information terminal in FIG. 23A may transmit and receive data wirelessly. Through wireless communication, desired book data or the like can be purchased and downloaded from an electronic book server.

Furthermore, the housing 902 in FIG. 23A may be equipped with an antenna or have a microphone function or a wireless communication function to be used as a mobile phone.

FIG. 23B illustrates an e-book reader terminal 910 including electronic paper. The e-book reader terminal 910 includes two housings 911 and 912. The housing 911 and the housing 912 are provided with a display portion 913 and a display portion 914, respectively. The housings 911 and 912 are connected by a hinge portion 915 and can be opened and closed with the hinge portion 915 as an axis. The housing 911 is provided with a power switch 916, an operation key 917, a speaker 918, and the like. The semiconductor device is provided in at least one of the housings 911 and 912. Thus, the e-book reader which achieves a smaller size and higher-speed operation can be obtained.

FIG. 23C is a television device, which includes a housing 921, a display portion 922, a stand 923, and the like. The television device 920 can operate with a switch of the housing 921 and a separate remote controller 924. The semiconductor device described in the above embodiments is provided in the housing 921 and the remote controller 924. Thus, the television device which achieves a smaller size and higher-speed operation can be obtained.

FIG. 23D illustrates a smartphone in which a main body 930 includes a display portion 931, a speaker 932, a microphone 933, operation buttons 934, and the like. The semiconductor device described in the above embodiments is provided in the main body 930. Thus, the smart phone which achieves a smaller size and higher-speed operation can be obtained.

FIG. 23E illustrates a digital camera, which includes a main body 941, a display portion 942, an operation switch 943, and the like. The semiconductor device described in the above embodiments is provided in the main body 941. Thus, the digital camera which achieves a smaller size and higher-speed operation can be obtained.

As described above, the semiconductor device described in the above embodiments is provided in each of the electronic devices described in this embodiment. Thus, the electronic devices which achieve reduction in power consumption can be obtained.

This application is based on Japanese Patent Application serial no. 2014-080845 filed with the Japan Patent Office on Apr. 10, 2014, the entire contents of which are hereby incorporated by reference.

What is claimed is:

1. A semiconductor device comprising:
a multiport SRAM comprising a first transistor;
a wiring electrically connected to the first transistor; and
a data memory portion comprising a second transistor and a capacitor,
wherein the first transistor comprises silicon in a channel formation region,
wherein the second transistor comprises an oxide semiconductor in a channel formation region,
wherein one of a source and a drain of the second transistor is electrically connected to a source or a drain of the first transistor,
wherein the capacitor is electrically connected to the other of the source and the drain of the second transistor,
wherein the source or the drain of the first transistor overlaps with the wiring,
wherein the wiring overlaps with the source or the drain of the second transistor, and
wherein the source or the drain of the second transistor overlaps with an electrode of the capacitor.

2. A semiconductor device comprising:
a multiport SRAM comprising a first transistor;
a wiring electrically connected to the first transistor; and
a data memory portion comprising a second transistor, a third transistor, and a capacitor,
wherein the first transistor comprises silicon in a channel formation region,
wherein the second transistor comprises an oxide semiconductor in a channel formation region,
wherein the third transistor comprises silicon in a channel formation region,
wherein one of a source and a drain of the second transistor is electrically connected to a source or a drain of the first transistor,
wherein the capacitor is electrically connected to the other of the source and the drain of the second transistor,
wherein the other of the source and the drain of the second transistor is electrically connected to a gate of the third transistor,
wherein a source or a drain of the third transistor is electrically connected to the source or the drain of the first transistor,
wherein the source or the drain of the first transistor overlaps with the wiring,
wherein the wiring overlaps with the source or the drain of the second transistor, and
wherein the source or the drain of the second transistor overlaps with an electrode of the capacitor.

3. The semiconductor device according to claim 2, wherein the third transistor is an n-channel transistor or a p-channel transistor included in an inverter.

4. An electronic component comprising:
the semiconductor device according to any one of claims 1 to 3; and
a lead electrically connected to the semiconductor device.

5. An electronic device comprising:
the electronic component according to claim 4; and
a display device.
